(19) United States
(12) Patent Application Publication
(10) Pub. No.: US 2026/0188208 A1
(43) Pub. Date: Jul. 2, 2026

(54) Pixel Drive Circuit, Driving Method Therefor, Display Substrate, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Hongting LU, Beijing (CN); Yipeng CHEN, Beijing (CN); Zhenglong YAN, Beijing (CN)

(21) Appl. No.: 18/727,701

(22) PCT Filed: Mar. 2, 2023
(86) PCT No.: PCT/CN2023/079277

§ 371 Date: Jul. 10, 2024

(51) Int. Cl. G09G 3/3233; H10K 59/131

(52) U.S. Cl. CPC G09G 3/3233; H10K 59/131; G09G 2300/0426; G09G 2300/0852; G09G 2300/0861; G09G 2310/08; G09G 2320/0209; G09G 2320/0233; G09G 2320/045; G09G 2330/021

(57) ABSTRACT

A the pixel drive circuit includes a node control sub-circuit, a light emitting control sub-circuit and a drive sub-circuit; the node control sub-circuit is configured to drive a signal of a first node, provide a signal of a second initial signal line to a second node, and provide a signal of a third initial signal line to a third node through signals of a first initial signal line, a data signal line and a first power supply line under control of signals of a first scan signal line, a second scan signal line, a third scan signal line and a fourth scan signal line; the light emitting control sub-circuit is configured to provide a signal of the first power supply line to the third node under control of a signal of the light emitting signal line; the drive sub-circuit is configured to output a drive current to a second node.

### CROSS-REFERENCE TO RELATED APPLICATIONS

The present application is a U.S. National Phase Entry of International Application PCT/CN2023/079277 having an international filing date of Mar. 2, 2023, and entitled “Pixel Drive Circuit, Driving Method Therefor, Display Substrate, and Display Apparatus”, contents of which should be construed as being incorporated herein by reference.

### TECHNICAL FIELD

The present disclosure relates to but is not limited to the field of display technologies, in particular to a pixel drive circuit and a method for driving the pixel drive circuit, a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matter described in the present disclosure in detail. This summary is not intended to limit the protection scope of claims.

In a first aspect, the present disclosure provides a pixel drive circuit configured to drive a light emitting device, and the pixel drive circuit includes a node control sub-circuit, a light emitting control sub-circuit, and a drive sub-circuit;
the node control sub-circuit is electrically connected to a first node, a second node, a third node, a first scan signal line, a second scan signal line, a third scan signal line, a fourth scan signal line, a first initial signal line, a second initial signal line, a third initial signal line, a data signal line and a first power supply line respectively, and the node control sub-circuit is configured to drive a signal of the first node, provide a signal of the second initial signal line to the second node, and provide a signal of the third initial signal line to the third node through signals of the first initial signal line, the data signal line and the third node under control of signals of the first scan signal line, the second scan signal line, the third scan signal line and the fourth scan signal line;
the light emitting control sub-circuit is electrically connected to a first power supply line, a light emitting signal line and the third node respectively, and is configured to provide a signal of the first power supply line to the third node under control of a signal of the light emitting signal line;
the drive sub-circuit is electrically connected to the first node, the second node, and the third node respectively, and is configured to output a drive current to the second node under control of signals of the first node and the third node;
the light emitting device is electrically connected to the second node and the second power supply line respectively.
the node control sub-circuit includes: an energy storage sub-circuit which includes: a first capacitor and a second capacitor, wherein the first capacitor and the second capacitor each include a first plate and a second plate;
the first plate of the first capacitor is electrically connected to the first power supply line, and the second plate of the first capacitor is electrically connected to a fourth node; and
the first plate of the second capacitor is electrically connected to the first node, and the second plate of the second capacitor is electrically connected to the fourth node.

In an exemplary implementation, the node control sub-circuit further includes: a reset sub-circuit, a compensation sub-circuit and a write sub-circuit;
the reset sub-circuit is electrically connected to the first node, the second node, the third node, the first scan signal line, the second scan signal line, the third scan signal line, the first initial signal line, the second initial signal line and the third initial signal line respectively, and the reset sub-circuit is configured to provide a signal of the first initial signal line to the first node under control of a signal of the first scan signal line, provide the signal of the second initial signal line to the second node under control of a signal of the second scan signal line, and provide the signal of the third initial signal line to the third node under control of a signal of the third scan signal line;
the compensation sub-circuit is electrically connected to the third node, the fourth node and the first scan signal line, respectively, and is configured to provide a signal of the third node to the fourth node under control of the signal of the first scan signal line to compensate a signal of the fourth node;
the write sub-circuit is electrically connected to the fourth node, the fourth scan signal line, and the data signal line respectively, and is configured to provide a signal of the data signal line to the fourth node under control of a signal of the fourth scan signal line; In an exemplary implementation, the reset sub-circuit includes a first transistor, a second transistor and a third transistor;
a gate electrode of the first transistor is connected to the first scan signal line, a first electrode of the first transistor is connected to the first initial signal line, and a second electrode of the first transistor is connected to the first node;
a gate electrode of the second transistor is connected to the second scan signal line, a first electrode of the second transistor is connected to the second initial signal line, and a second electrode of the second transistor is connected to the second node; and
a gate electrode of the third transistor is electrically connected to the third scan signal line, a first electrode of the third transistor is electrically connected to the third initial signal line, and a second electrode of the third transistor is electrically connected to the third node.

In an exemplary implementation, the compensation sub-circuit includes a fourth transistor, and the write transistor includes a fifth transistor;
a gate electrode of the fourth transistor is electrically connected to the first scan signal line, a first electrode of the fourth transistor is electrically connected to the fourth node, and a second electrode of the fourth transistor is electrically connected to the third node; and
a gate electrode of the fifth transistor is electrically connected to the fourth scan signal line, a first electrode of the fifth transistor is electrically connected to the data signal line, and a second electrode of the fifth transistor is electrically connected to the fourth node.

In an exemplary implementation, the node control sub-circuit further includes: a first transistor to a fifth transistor, the drive sub-circuit includes a sixth transistor, and the light emitting control sub-circuit includes a seventh transistor;
a gate electrode of the first transistor is connected to the first scan signal line, a first electrode of the first transistor is connected to the first initial signal line, and a second electrode of the first transistor is connected to the first node;
a gate electrode of the second transistor is connected to the second scan signal line, a first electrode of the second transistor is connected to the second initial signal line, and a second electrode of the second transistor is connected to the second node; and
a gate electrode of the third transistor is electrically connected to the third scan signal line, a first electrode of the third transistor is electrically connected to the third initial signal line, and a second electrode of the third transistor is electrically connected to the third node;
a gate electrode of the fourth transistor is electrically connected to the first scan signal line, a first electrode of the fourth transistor is electrically connected to the fourth node, and a second electrode of the fourth transistor is electrically connected to the third node;
a gate electrode of the fifth transistor is electrically connected to the fourth scan signal line, a first electrode of the fifth transistor is electrically connected to the data signal line, and a second electrode of the fifth transistor is electrically connected to the fourth node;
a gate electrode of the sixth transistor is electrically connected to the first node, a first electrode of the sixth transistor is electrically connected to the third node, and a second electrode of the sixth transistor is electrically connected to the second node; and
a gate electrode of the seventh transistor is electrically connected to the light emitting signal line, a first electrode of the seventh transistor is electrically connected to the first power supply line, and a second electrode of the seventh transistor is electrically connected to the third node.

In an exemplary implementation, the first transistor, the fourth transistor, and the fifth transistor are oxide transistors and are N-type transistors, and the second transistor, the third transistor, the sixth transistor, and the seventh transistor are P-type transistors;
a length of a channel region of an active layer of the sixth transistor is larger than a length of a channel region of an active layer of any one of the first transistor to the fifth transistor and the seventh transistor, a width of the channel region of the active layer of the sixth transistor is larger than a width of the channel region of the active layer of any one of the first transistor to the fifth transistor and the seventh transistor, and a width-length ratio of the channel region of the active layer of the sixth transistor is smaller than a width-length ratio of the channel region of the active layer of any one of the first transistor to the fifth transistor and the seventh transistor.

In an exemplary implementation, the signal of the first scan signal line and the signal of the second scan signal line are mutually inverted signals;
when a signal of the third scan signal line is an active level signal, the signals of the first scan signal line and the second scan signal line are active level signals, and signals of the fourth scan signal line and the light emitting signal line are inactive level signals;
when the signal of the fourth scan signal line is an active level signal, the signals of the first scan signal line, the second scan signal line, the third scan signal line and the light emitting signal line are inactive level signals;
when the signal of the light emitting signal line is an active level signal, signals of the first scan signal line, the second scan signal line, the third scan signal line and the fourth scan signal line are inactive level signals; and
a duration for which a signal of any one of the first scan signal line and the second scan signal line is an active level signal is longer than a duration for which a signal of any one of the third scan signal line and the fourth scan signal line is an active level signal.

In an exemplary implementation, a signal of the first initial signal line and a signal of the second initial signal line are a same signal, and a voltage value of the signal of the first initial signal line is smaller than a voltage value of the signal of the third initial signal line; and
the voltage value of the signal of the second initial signal line is greater than the voltage value of the signal of the second power supply line.

In a second aspect, the present disclosure further provides a display substrate, including a base substrate and a plurality of sub-pixels arranged on the base substrate, and at least one sub-pixel includes the above pixel drive circuit and the light emitting device driven by the pixel drive circuit.

In the exemplary implementation, further including: a drive circuit layer and a light emitting structure layer which are sequentially stacked on the base substrate, wherein the drive circuit layer includes a plurality of pixel drive circuits, a plurality of light emitting signal lines, a plurality of first initial signal lines, a plurality of second initial signal lines, a plurality of third initial signal lines, a plurality of first scan signal lines, a plurality of second scan signal lines, a plurality of third scan signal lines, a plurality of fourth scan signal lines, a plurality of first power supply lines and a plurality of data signal lines, and the light emitting structure layer includes a light emitting device; and any one of the light emitting signal lines, the first initial signal lines, the second initial signal lines, the third initial signal lines, the first scan signal lines, the second scan signal lines, the third scan signal lines and the fourth scan signal lines extends at least partially along a first direction, and any one of the first power supply lines and the data signal lines extends at least partially along a second direction, wherein the first direction intersects with the second direction.

In an exemplary implementation, the drive circuit layer further includes a plurality of power supply connection lines extending at least partially along the first direction; and
at least one power supply connection line is respectively connected to a pixel drive circuit and at least one first power supply line respectively.

In an exemplary implementation, the sub-drive circuit layer further includes a first connection electrode;
the first connection electrode is respectively connected to the pixel drive circuit, a power supply connection line and a first power supply line respectively; and
an orthographic projection of the first connection electrode on the base substrate is at least partially overlapped with orthographic projections of the power supply connection line and the first power supply line on the base substrate.

In an exemplary implementation, the first initial signal lines and the second initial signal lines are same signal lines, and the drive circuit layer further includes a plurality of initial connection lines extending at least partially along the second direction;
at least one initial connection line connected to the pixel drive circuit and at least one first initial signal line respectively; and
an orthographic projection of an initial connection line on the base substrate is located between orthographic projections of data signal lines connected by two adjacent columns of sub-pixels connected by the initial connection line on the base substrate.

In an exemplary implementation, the first scan signal line includes a first sub-signal line and a second sub-signal line electrically connected to each other, and the fourth scan signal line includes a third sub-signal line and a fourth sub-signal line electrically connected to each other; and
an orthographic projection of the first sub-signal line on the base substrate is at least partially overlapped with an orthographic projection of the second sub-signal line on the base substrate, and an orthographic projection of the third sub-signal line on the base substrate is at least partially overlapped with an orthographic projection of the fourth sub-signal line on the base substrate.

In an exemplary implementation, the pixel drive circuit includes a first transistor to a seventh transistor, and a first capacitor and a second capacitor, each of the first capacitor and the second capacitor includes a first plate and a second plate respectively, and the drive circuit layer includes a first semiconductor layer, a first conductive layer, a second conductive layer, a second semiconductor layer, a third conductive layer, a fourth conductive layer and a fifth conductive layer which are sequentially arranged on the base substrate;
the first semiconductor layer at least includes: an active layer of the second transistor, an active layer of the third transistor, an active layer of the sixth transistor and an active layer of the seventh transistor located in at least one pixel;
the first conductive layer at least includes: a light emitting signal line, a second scan signal line, a third scan signal line and a first plate of the first capacitor, a first plate of the second capacitor, a gate electrode of the second transistor, a gate electrode of the third transistor, a control electrode of the sixth transistor and a gate electrode of the seventh transistor located in at least one sub-pixel;
the second conductive layer at least includes: the first sub-signal line of the first scan signal line, the third sub-signal line of the fourth scan signal line, the second plate of the first capacitor and the second plate of the second capacitor located in at least one sub-pixel;
the second semiconductor layer at least includes: an active layer of the first transistor, an active layer of the fourth transistor and an active layer of the fifth transistor located in at least one sub-pixel;
the third conductive layer at least includes: the second sub-signal line of the first scan signal line, the fourth sub-signal line of the fourth scan signal line, the power supply connection line, the first initial signal line, the second initial signal line and the third initial signal line;
the fourth conductive layer at least includes: an initial connection line, and a first connection electrode and first electrodes and second electrodes of the first transistor to the seventh transistor located in at least one sub-pixel; and
the fifth conductive layer at least includes: a first power supply line and a data signal line.

In an exemplary implementation, the drive circuit layer further includes a light shielding layer arranged between the base substrate and the first semiconductor layer;
the light shielding layer at least includes: a light shielding structure located in at least one sub-pixel, and the light shielding structures of adjacent sub-pixels are connected to each other; and
an orthographic projection of the light shielding structure on the base substrate is at least partially overlapped with an orthographic projection of the gate electrode of the sixth transistor on the base substrate.

In an exemplary implementation, the light shielding structure includes a first light shielding portion, a second light shielding portion, a third light shielding portion, and a fourth light shielding portion;
an orthographic projection of the first light shielding portion on the base substrate is at least partially overlapped with an orthographic projection of the active layer of the sixth transistor on the base substrate, an orthographic projection of the second light shielding portion on the base substrate is at least partially overlapped with an orthographic projection of the active layer of the seventh transistor on the base substrate, an orthographic projection of the third light shielding portion on the base substrate is at least partially overlapped with an orthographic projection of the active layer of the third transistor on the base substrate, and an orthographic projection of the fourth light shielding portion on the base substrate is at least partially overlapped with an orthographic projection of the active layer of the second transistor on the base substrate.

In an exemplary implementation, the light shielding structure includes a light shielding portion, a first light shielding connection portion, a second light shielding connection portion, a third light shielding connection portion, and a fourth light shielding connection portion; and
an orthographic projection of the light shielding portion on the base substrate is at least partially overlapped with an orthographic projection of the active layer of the sixth transistor on the base substrate, and an orthographic projection of any one of the first light shielding connection portion, the second light shielding connection portion, the third light shielding connection portion and the fourth light shielding connection portion on the base substrate is not overlapped with an orthographic projection of any one of the active layer of the second transistor, the active layer of the third transistor and the active layer of the seventh transistor on the base substrate.

In an exemplary implementation, a light emitting signal line connected to a sub-pixel is located on a side of a first plate of a second capacitor of the sub-pixel away from a first plate of a first capacitor of the sub-pixel, a second scan signal line connected to the sub-pixel is located on a side of the first plate of the first capacitor of the sub-pixel away from the first plate of the second capacitor of the sub-pixel, and a third scan signal line connected to the sub-pixel is located on a side of the second scan signal line connected to the sub-pixel away from the first plate of the first capacitor of the sub-pixel.

In an exemplary implementation, a second plate of the first capacitor and a second plate of the second capacitor are connected to each other to form an integral structure, and are provided with a first via hole and a second via hole, wherein the first via hole exposes the first plate of the first capacitor, and the second via hole exposes the second plate of the second capacitor;
the third sub-signal line of the fourth scan signal line is located on a side of the first sub-signal line of the first scan signal line away from the integral structure of the second plate of the first capacitor and the second plate of the second capacitor; and
an orthographic projection of the first sub-signal line of the first scan signal line connected to the sub-pixel on the base substrate is located between an orthographic projection of a light emitting signal line connected to the sub-pixel on the base substrate and an orthographic projection of the first plate of a second capacitor of the sub-pixel on the base substrate, and an orthographic projection of the third sub-signal line of the fourth scan signal line connected to the sub-pixel is located on a side of the orthographic projection of the light emitting signal line connected to the sub-pixel on the base substrate away from the orthographic projection of the first plate of the second capacitor of the sub-pixel on the base substrate.

In an exemplary implementation, a second sub-signal line of a first scan signal line connected to the sub-pixel is located on a side of a fourth sub-signal line of a fourth scan signal line connected to the sub-pixel, a power supply connection line connected to the sub-pixel is located on a side of the second sub-signal line of the first scan signal line connected to the sub-pixel away from the fourth sub-signal line of the fourth scan signal line connected to the sub-pixel, a first initial signal line connected to the sub-pixel is located on a side of the power supply connection line connected to the sub-pixel away from the second sub-signal line of the first scan signal line connected to the sub-pixel, and a third initial signal line connected to the sub-pixel is located on a side of the first initial signal line connected to the sub-pixel away from the power supply connection line connected to the sub-pixel;
an orthographic projection of the fourth sub-signal line of the fourth scan signal line connected to the sub-pixel on the base substrate is located on a side of an orthographic projection of the light emitting signal line connected to the sub-pixel on the base substrate away from the orthographic projection of the first plate of the second capacitor of the sub-pixel on the base substrate;
an orthographic projection of the second sub-signal line of the first scan signal line connected to the sub-pixel on the base substrate is located between the orthographic projection of the light emitting signal line connected to the sub-pixel on the base substrate and the orthographic projection of the first plate of the second capacitor of the sub-pixel on the base substrate;
an orthographic projection of the power supply connection line connected to the sub-pixel on the base substrate is at least partially overlapped with an orthographic projection of the integral structure of the second plate of the first capacitor and the second plate of the second capacitor of the sub-pixel on the base substrate, and is located between the orthographic projection of the first sub-signal line of the first scan signal line on the base substrate and an orthographic projection of the second scan signal line on the base substrate;
an orthographic projection of the first initial signal line connected to the sub-pixel on the base substrate is at least partially overlapped with an orthographic projection of the second scan signal line connected to the sub-pixel on the base substrate, and is located between the orthographic projection of the first plate of the first capacitor of the sub-pixel on the base substrate and an orthographic projection of the third scan signal line connected to the sub-pixel on the base substrate; and
an orthographic projection of the third initial signal line connected to the sub-pixel on the base substrate is at least partially overlapped with the orthographic projection of the third scan signal line connected to the sub-pixel on the base substrate, and is located on a side of an orthographic projection of the second scan signal line connected to the sub-pixel on the base substrate away from an orthographic projection of the first plate of the first capacitor of the sub-pixel on the base substrate.

In an exemplary implementation, the power supply connection line includes a signal main body line, a first convex portion, a second convex portion and a third convex portion, wherein the signal main body line extends along the first direction, the first convex portion is located on a side of the signal main body line close to the second sub-signal line of the first scan signal line, the second convex portion and the third convex portion are located on a side of the signal main body line away from the second sub-signal line of the first scan signal line, and the second convex portion and third convex portion are arranged along the first direction;
orthographic projections of the second convex portion and the third convex portion on the base substrate are at least partially overlapped with an orthographic projection of the integral structure of the second plate of the first capacitor and the second plate of the second capacitor on the base substrate; and
an orthographic projection of the first via hole on the base substrate is located between the orthographic projection of the second convex portion on the base substrate and the orthographic projection of the third convex portion on the base substrate.

In an exemplary implementation, an orthographic projection of the first connection electrode on the base substrate is at least partially overlapped with the orthographic projections of the signal main body line, the second convex portion and the third convex portion of the power supply connection line on the base substrate, and is not overlapped with an orthographic projection of the first convex portion of the power supply connection line on the base substrate.

In an exemplary implementation, an orthographic projection of the first power supply line on the base substrate is at least partially overlapped with orthographic projections of the integral structure of the second plate of the first capacitor and the second plate of the second capacitor, the first connection electrode, the signal main body portion and the second convex portion of the power supply connection line on the base substrate; and
an orthographic projection of a first power supply line connected to the sub-pixel on the base substrate is located on a side of a data signal line connected to the sub-pixel away from an initial connection line connected to the sub-pixel.

In a third aspect, the present disclosure further provides a display apparatus including the display substrate described above.

In a fourth aspect, the present disclosure further provides a method for driving a pixel drive circuit configured to drive the pixel drive circuit above-described, and the method includes following steps:
a node control sub-circuit driving a signal of a first node, providing a signal of the second initial signal line to a second node, and providing a signal of the third initial signal line to a third node through signals of a first initial signal line, a data signal line and a first power supply line under control of signals of a first scan signal line, a second scan signal line, a third scan signal line and a fourth scan signal line; and
a light emitting control sub-circuit providing a signal of the first power supply line to the third node under control of a signal of the light emitting signal line, and the drive sub-circuit outputting a drive current to the second node under control of signals of the first node and the third node.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solutions of the present disclosure, and do not form limitations on the technical solutions of the present disclosure.

FIG. 1 is a schematic structural diagram of a pixel drive circuit according to an embodiment of the present disclosure.

FIG. 2 is a schematic structural diagram of a node control sub-circuit.

FIG. 3 is an equivalent circuit diagram of a node control sub-circuit.

FIG. 4 is an equivalent circuit diagram of a light emitting control sub-circuit and a drive sub-circuit.

FIG. 5 is an equivalent circuit diagram of a pixel drive circuit.

FIG. 6 is a working timing diagram of a pixel drive circuit.

FIG. 7 is a first schematic structural diagram of a display substrate according to an embodiment of the present disclosure.

FIG. 8 is a second schematic structural diagram of a display substrate according to an embodiment of the present disclosure.

FIG. 9 is a first schematic diagram of a partial film layer of a display substrate.

FIG. 10 is a second schematic diagram of a partial film layer of a display substrate.

FIG. 11 is a schematic diagram of a pattern of a light shielding layer of the display substrate provided in FIG. 7.

FIG. 12 is a schematic diagram of a pattern of a light shielding layer of the display substrate provided in FIG. 8.

FIG. 13 is a schematic diagram of a pattern of a first semiconductor layer of the display substrate provided in FIG. 7 and FIG. 8.

FIG. 14 is a schematic diagram of the display substrate provided in FIG. 7 after the pattern of the first semiconductor layer is formed.

FIG. 15 is a schematic diagram of the display substrate provided in FIG. 8 after the pattern of the first semiconductor layer is formed.

FIG. 16 is a schematic diagram of a pattern of a first conductive layer of the display substrate provided in FIG. 7 and FIG. 8.

FIG. 17 is a schematic diagram of the display substrate provided in FIG. 7 after the pattern of the first conductive layer is formed.

FIG. 18 is a schematic diagram of the display substrate provided in FIG. 8 after the pattern of the first conductive layer is formed.

FIG. 19 is a schematic diagram of a pattern of a second conductive layer of the display substrate provided in FIG. 7 and FIG. 8.

FIG. 20 is a schematic diagram of the display substrate provided in FIG. 7 after the pattern of the second conductive layer is formed.

FIG. 21 is a schematic diagram of the display substrate provided in FIG. 8 after the pattern of the second conductive layer is formed.

FIG. 22 is a schematic diagram of a pattern of a second semiconductor layer of the display substrate provided in FIG. 7 and FIG. 8.

FIG. 23 is a schematic diagram of the display substrate provided in FIG. 7 after the pattern of the second semiconductor layer is formed.

FIG. 24 is a schematic diagram of the display substrate provided in FIG. 8 after the pattern of the second semiconductor layer is formed.

FIG. 25 is a schematic diagram of a pattern of a third conductive layer of the display substrate provided in FIG. 7 and FIG. 8.

FIG. 26 is a schematic diagram of the display substrate provided in FIG. 7 after the pattern of the third conductive layer is formed.

FIG. 27 is a schematic diagram of the display substrate provided in FIG. 8 after the pattern of the third conductive layer is formed.

FIG. 28 is a schematic diagram of the display substrate provided in FIG. 7 after a pattern of a seventh insulation layer is formed.

FIG. 29 is a schematic diagram of the display substrate provided in FIG. 8 after a pattern of a seventh insulation layer is formed.

FIG. 30 is a schematic diagram of a pattern of a fourth conductive layer of the display substrate provided in FIG. 7 and FIG. 8.

FIG. 31 is a schematic diagram of the display substrate provided in FIG. 7 after the pattern of the fourth conductive layer is formed.

FIG. 32 is a schematic diagram of the display substrate provided in FIG. 8 after the pattern of the fourth conductive layer is formed.

FIG. 33 is a schematic diagram of the display substrate provided in FIG. 7 after a pattern of an eighth insulation layer is formed.

FIG. 34 is a schematic diagram of the display substrate provided in FIG. 8 after a pattern of an eighth insulation layer is formed.

FIG. 35 is a schematic diagram of a pattern of a fifth conductive layer of the display substrate provided in FIG. 7 and FIG. 8.

FIG. 36 is a schematic diagram of the display substrate provided in FIG. 7 after the pattern of the fifth conductive layer is formed.

FIG. 37 is a schematic diagram of the display substrate provided in FIG. 8 after the pattern of the fifth conductive layer is formed.

### DETAILED DESCRIPTION

To make objectives, technical solutions, and advantages of the present disclosure clearer, the embodiments of the present disclosure will be described in detail below with reference to the accompany drawings. It is to be noted that implementations may be implemented in a plurality of different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, wordings “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three lines, i.e., a gate electrode, a drain electrode, and a source electrode. The transistor has a channel region between the drain electrode (drain electrode line, drain region, or drain electrode) and the source electrode (source electrode line, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of constituent elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 800 or more and 1000 or less, and thus also includes a state in which the angle is 850 or more and 950 or less.

In the specification, a “film” and a “layer” are interchangeable. For example, a “conductive layer” may be replaced with a “conductive thin film” sometimes. Similarly, an “insulation film” may be replaced with an “insulation layer” sometimes.

In the specification, “arranged in a same layer” refers to a structure formed by patterning two (or more than two) structures through a same patterning process, and their materials may be the same or different. For example, materials of precursors for forming a plurality of structures arranged in a same layer are the same, and final materials may be the same or different.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

A Low Temperature Poly-Silicon (LTPS for short) technology is used in a display substrate. The LTPS technology has advantages such as high resolution, high response speed, high brightness, and high aperture ratio. Although it is welcomed by the market, the LTPS technology also has some defects, such as relatively high production cost and relatively large power consumption. At this time, a technology solution of Low Temperature Polycrystalline Oxide (LTPO for short) came into being. Compared with the LTPS technology, in the LTPO technology, a leakage current is smaller, pixel point response is faster, and an additional layer of an oxide is added to a display substrate, which reduces energy consumption required for exciting pixel points, thus reducing power consumption during screen display. However, display products using LTPO technology have more complex manufacturing processes and higher cost, with the emergence of high mobility oxide materials, it is possible to drive OLED devices by Oxide, by this time, display products using Oxide technology become possible. Compared with the LTPO technology, the Oxide technology has become a new mainstream trend with simple process, lower cost and smaller leakage current. But in display products using oxide technology, charging time of pixel drive circuits is short, which cannot meet requirements of high-resolution display substrates, and affects display effects of display products.

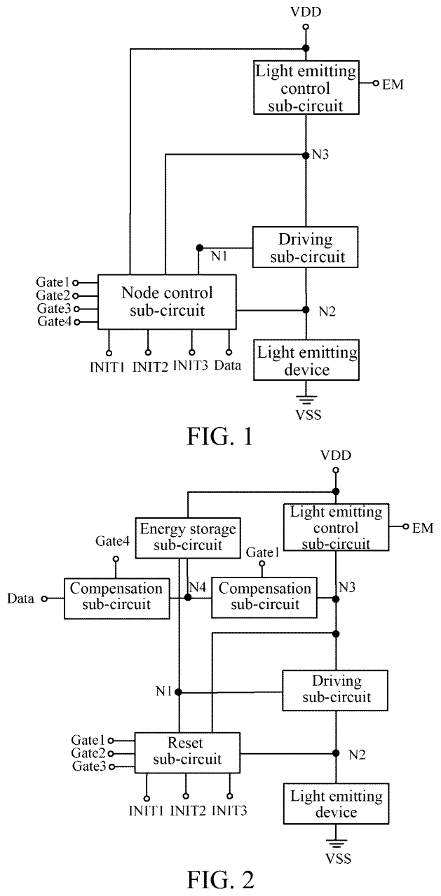

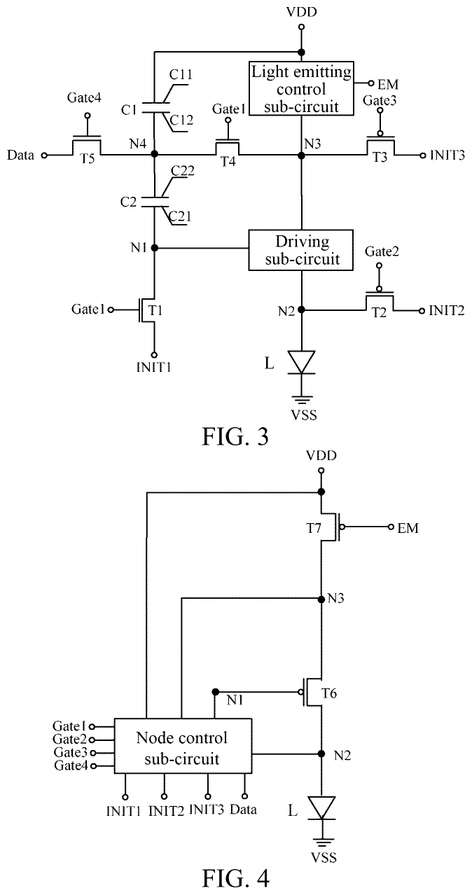

FIG. 1 is a schematic structural diagram of a pixel drive circuit according to an embodiment of the present disclosure, FIG. 2 is a schematic structural diagram of a node control sub-circuit, and FIG. 3 is an equivalent circuit diagram of a node control sub-circuit. As shown in FIGS. 1 to 3, the pixel drive circuit according to an embodiment of the present disclosure is configured to drive a light emitting device to emit light, and the pixel drive circuit includes a node control sub-circuit, a light emitting control sub-circuit, and a drive sub-circuit.

In an exemplary implementation, as shown in FIG. 1, the node control sub-circuit may be electrically connected to a first node N1, a second node N2, a third node N3, a first scan signal line Gate1, a second scan signal line Gate2, a third scan signal line Gate3, a fourth scan signal line Gate4, a first initial signal line INIT1, a second initial signal line INIT2, a third initial signal line INIT3, a data signal line Data and a first power supply line VDD respectively, and the node control sub-circuit is configured to drive a signal of the first node N1, provide a signal of the initial signal line INIT2 to the second node N2, provide a signal of the initial signal line INIT3 to the third node N3, and provide a signal of the third node N3 or the data signal line Data to a fourth node N4 through signals of the first initial signal line INIT1, the data signal line Data, the third node N3 under control of signals of the first scan signal line Gate1, the second scan signal line Gate2, the third scan signal line Gate3 and the fourth scan signal line Gate4.

In an exemplary implementation, as shown in FIGS. 1 to 3, the node control sub-circuit includes an energy storage sub-circuit, which is electrically connected to the first node N1, the fourth node N4 and the first power supply line VDD respectively, and is configured to store a voltage difference between signals of the first node N1 and the fourth node N4, and a voltage difference between signals of the fourth node N4 and the first power supply line VDD to drive the signal of the first node N1 through the signals of the first power supply line and the fourth node N4.

In an exemplary implementation, as shown in FIG. 3, the energy storage sub-circuit may include a first capacitor C1 and a second capacitor C2, and each of the first capacitor C1 and the second capacitor C2 includes a first plate and a second plate. Herein, a first plate C11 of the first capacitor C1 is electrically connected to the first power supply line VDD, and a second plate C12 of the first capacitor C1 is electrically connected to the fourth node N4. A first plate C21 of the second capacitor C2 is electrically connected to the first node N1, and a second plate C22 of the second capacitor C2 is electrically connected to the fourth node N4.

In an exemplary implementation, as shown in FIG. 1, the light emitting control sub-circuit may be electrically connected to the first power supply line VDD, the light emitting signal line EM and the third node N3, respectively, and is configured to provide a signal of the first power supply line VDD to the third node N3 under control of a signal of the light emitting signal line EM.

In an exemplary implementation, as shown in FIG. 1, the drive sub-circuit is electrically connected to the first node N1, the second node N2, and the third node N3 respectively, and is configured to output a drive current to the second node N2 under control of signals of the first node N1 and the third node N3.

In an exemplary implementation, as shown in FIG. 1, the light emitting device is electrically connected to the second node N2 and a second power supply line VSS respectively.

In an exemplary implementation, the first power supply line VDD may continuously provide a high-voltage power supply signal, and the second power supply line VSS may continuously provide a low-voltage power supply signal.

In an exemplary implementation, a voltage value of the signal of the first power supply line VDD may be about 2.5 volts (V) to 3 volts (V), and for example, the voltage value of the signal of the first power supply line VDD may be about 2.8 volts (V).

In an exemplary implementation, a voltage value of the signal of the second power supply line VSS may be about −3 volts (V) to −3.5 volts (V), and for example, a voltage value of the signal of the second power supply line VSS may be about −3.2 volts (V).

In an exemplary implementation, a voltage value of the signal of the second power supply line VSS may be about −3 volts (V) to −3.5 volts (V), and for example, a voltage value of the signal of the second power supply line VSS may be about −3.2 volts (V).

In an exemplary implementation, the light emitting device may be an Organic Light Emitting Diode (OLED) including a first electrode (anode), an organic emitting layer, and a second electrode (cathode) that are stacked. For example, an anode of the organic light emitting diode is electrically connected to the second node N2, and a cathode of the organic light emitting diode is electrically connected to the second power supply line VSS.

In an exemplary implementation, the organic emitting layer may include a Hole Injection Layer (HIL), a Hole Transport Layer (HTL), an EMectron Block Layer (EBL), an Emitting Layer (EML), a Hole Block Layer (HBL), an EMectron Transport Layer (ETL), and an EMectron Injection Layer (EIL) that are stacked. In an exemplary implementation, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

The pixel drive circuit according to an embodiment of the present disclosure is configured to drive a light emitting device, and the pixel drive circuit includes a node control sub-circuit, a light emitting control sub-circuit and a drive sub-circuit. The node control sub-circuit is electrically connected to a first node, a second node, a third node, a first scan signal line, a second scan signal line, a third scan signal line, a fourth scan signal line, a first initial signal line, a second initial signal line, a third initial signal line, a data signal line and a first power supply line respectively, and is configured to drive a signal of the first node, provide a signal of the second initial signal line to the second node and provide a signal of the third initial signal line to the third node through signals of the first initial signal line, the data signal line and the third node under control of signals of the first scan signal line, the second scan signal line, the third scan signal line and the fourth scan signal line. The light emitting control sub-circuit is electrically connected to the first power supply line, the light emitting signal line, and the third node respectively, and is configured to provide the signal of the first power supply line to the third node under control of a signal of the light emitting signal line. The drive sub-circuit is electrically connected to the first node, the second node, and the third node respectively, and is configured to output a drive current to the second node under control of signals of the first node and the third node. The light emitting device is electrically connected to the second node and the second power supply line respectively. The node control sub-circuit includes an energy storage sub-circuit, which includes a first capacitor and a second capacitor, wherein the first capacitor and the second capacitor each include a first plate and a second plate. The first plate of the first capacitor is electrically connected to the first power supply line, and the second plate of the first capacitor is electrically connected to the fourth node. The first plate of the second capacitor is electrically connected to the first node, and the second plate of the second capacitor is electrically connected to the fourth node. In the present disclosure, the node control sub-circuit, the light emitting control sub-circuit and the drive sub-circuit are provided, and the pixel drive circuit may be compensated through the signal of the second initial signal line by cooperation of the node control sub-circuit, the light emitting control sub-circuit and the drive sub-circuit, thus increasing compensation time of the pixel drive circuit, prolonging charging time of the pixel drive circuit and improving reliability of the pixel drive circuit.

In an exemplary implementation, as shown in FIG. 2, the node control sub-circuit may further include: a reset sub-circuit, a compensation sub-circuit and a write sub-circuit.

As shown in FIG. 2, the reset sub-circuit is electrically connected to the first node N1, the second node N2, the third node N3, the first scan signal line Gate1, the second scan signal line Gate2, the third scan signal line Gate3, the first initial signal line INIT1, the second initial signal line INIT2 and the third initial signal line INIT3 respectively, and the reset sub-circuit is configured to provide a signal of the first initial signal line INIT1 to the first node N1 under control of a signal of the first scan signal line Gate1, provide the signal of the second initial signal line INIT2 to the second node N2 under control of the signal of the second scan signal line Gate2, and provide the signal of the third initial signal line INIT3 to the third node N3 under the control of the signal of the third scan signal line Gate3. The compensation sub-circuit is electrically connected to the third node N3, the fourth node N4 and the first scan signal line Gate1 respectively, and is configured to provide a signal of the third node N3 to the fourth node N4 under control of a signal of the first scan signal line Gate1 to compensate a signal of the fourth node N4. The write sub-circuit is electrically connected to the fourth node N4, the fourth scan signal line Gate4, and the data signal line Data respectively, and is configured to provide a signal of the data signal line Data to the fourth node N4 under control of a signal of the fourth scan signal line Gate4.

In an exemplary implementation, as shown in FIG. 3, the reset sub-circuit may include a first transistor T1, a second transistor T2, and a third transistor T3, the compensation sub-circuit may include a fourth transistor T4, and the write transistor may include a fifth transistor T5. Herein, a gate electrode of the first transistor T1 is electrically connected to the first scan signal line Gate1, a first electrode of the first transistor T1 is electrically connected to the first initial signal line INIT1, and a second electrode of the first transistor T1 is electrically connected to the first node N1. A gate electrode of the second transistor T2 is electrically connected to the second scan signal line Gate2, a first electrode of the second transistor T2 is electrically connected to the second initial signal line INIT2, and a second electrode of the second transistor T2 is electrically connected to the second node N2. A gate electrode of the third transistor T3 is electrically connected to the third scan signal line Gate3, a first electrode of the third transistor T3 is electrically connected to the third initial signal line INIT3, and a second electrode of the second transistor T2 is electrically connected to the third node N3. A gate electrode of the fourth transistor T4 is electrically connected to the first scan signal line Gate1, a first electrode of the fourth transistor T4 is electrically connected to the fourth node N4, and a second electrode of the fourth transistor T4 is electrically connected to the third node N3. A gate electrode of the fifth transistor T5 is electrically connected to the fourth scan signal line Gate4, a first electrode of the fifth transistor T5 is electrically connected to the data signal line Data, and a second electrode of the fifth transistor T5 is electrically connected to the fourth node N4.

FIG. 4 is an equivalent circuit diagram of a light emitting control sub-circuit and a drive sub-circuit. As shown in FIG. 4 the drive sub-circuit may include a sixth transistor T6, and the light emitting control sub-circuit may include a seventh transistor T7. Herein, a gate electrode of the sixth transistor T6 is electrically connected to the first node N1, a first electrode of the sixth transistor T6 is electrically connected to the third node N3, and a second electrode of the sixth transistor T6 is electrically connected to the second node N2. A gate electrode of the seventh transistor T7 is electrically connected to the light emitting signal line EM, a first electrode of the seventh transistor T7 is electrically connected to the first power supply line VDD, and a second electrode of the seventh transistor T7 is electrically connected to the third node N3.

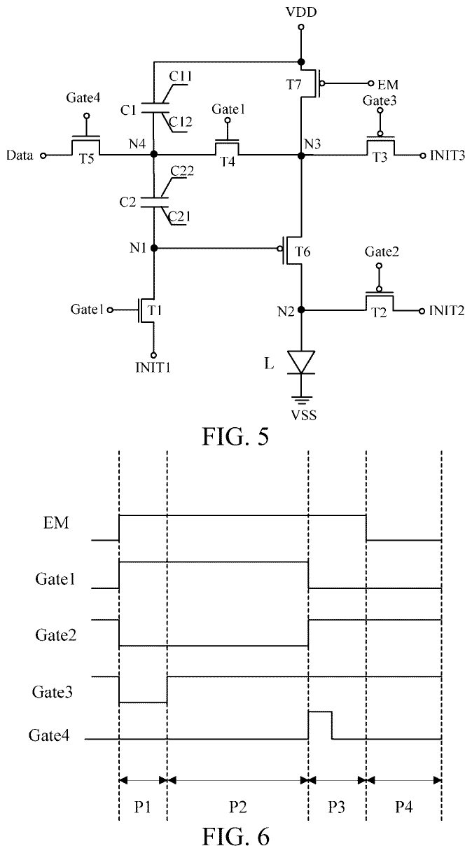

FIG. 5 is an equivalent circuit diagram of a pixel drive circuit. As shown in FIG. 5, in an exemplary implementation, the node control sub-circuit includes a first transistor T1 to a fifth transistor T5, a first capacitor C1 and a second capacitor C2. The drive sub-circuit includes a sixth transistor T6. The light emitting control sub-circuit includes a seventh transistor T7. The first capacitor C1 and the second capacitor C2 each include a first plate and a second plate. Herein, a gate electrode of the first transistor T1 is electrically connected to the first scan signal line Gate1, a first electrode of the first transistor T1 is electrically connected to the first initial signal line INIT1, and a second electrode of the first transistor T1 is electrically connected to the first node N1. A gate electrode of the second transistor T2 is electrically connected to the second scan signal line Gate2, a first electrode of the second transistor T2 is electrically connected to the second initial signal line INIT2, and a second electrode of the second transistor T2 is electrically connected to the second node N2. A gate electrode of the third transistor T3 is electrically connected to the third scan signal line Gate3, a first electrode of the third transistor T3 is electrically connected to the third initial signal line INIT3, and a second electrode of the third transistor T2 is electrically connected to the third node N3. A gate electrode of the fourth transistor T4 is electrically connected to the first scan signal line Gate1, a first electrode of the fourth transistor T4 is electrically connected to the fourth node N4, and a second electrode of the fourth transistor T4 is electrically connected to the third node N3. A gate electrode of the fifth transistor T5 is electrically connected to the fourth scan signal line Gate4, a first electrode of the fifth transistor T5 is electrically connected to the data signal line Data, and a second electrode of the fifth transistor T5 is electrically connected to the fourth node N4. A gate electrode of the sixth transistor T6 is electrically connected to the first node N1, a first electrode of the sixth transistor T6 is electrically connected to the third node N3, and a second electrode of the sixth transistor T6 is electrically connected to the second node N2. A gate electrode of the seventh transistor T7 is electrically connected to the light emitting signal line EM, a first electrode of the seventh transistor T7 is electrically connected to the first power supply line VDD, and a second electrode of the seventh transistor T7 is electrically connected to the third node N3. A first plate C11 of the first capacitor C1 is electrically connected to the first power supply line VDD, and a second plate C12 of the first capacitor C1 is electrically connected to the fourth node N4. A first plate C21 of the second capacitor C2 is electrically connected to the first node N1, and a second plate C22 of the second capacitor C2 is electrically connected to the fourth node N4.

In an exemplary implementation, the first transistor T1 may be referred to as a first node reset transistor. When a signal of the first scan signal line Gate1 is an active level signal, a signal of the first initial signal line INIT1 is written to the first node N1.

In an exemplary implementation, the second transistor T2 may be referred to as a second node reset transistor. When a signal of the second scan signal line Gate2 is an active level signal, a signal of the second initial signal line INIT2 is written to the second node N2 (also an anode of the light emitting device L).

In an exemplary implementation, the third transistor T3 may be referred to as a third node reset transistor. When a signal of the third scan signal line Gate3 is an active level signal, a signal of the third initial signal line INIT3 is written to the third node N3.

In an exemplary implementation, the fourth transistor T4 may be referred to as a compensation transistor. When the signal of the first scan signal line Gate1 is an active level signal, a signal of the third node N3 is written to the fourth node N4 to compensate a signal of the fourth node N4.

In an exemplary implementation, the fifth transistor T5 may be referred to as a write transistor. When a signal of the fourth scan signal line Gate4 is an active level signal, a signal of the data signal line Data is written to the second node N2.

In an exemplary implementation, the third transistor T6 may be referred to as a drive transistor. The sixth transistor T6 determines a drive current flowing between the first power supply line VDD and the second power supply line VSS according to a potential difference between the gate electrode and the first electrode of the sixth transistor T6.

In an exemplary implementation, the seventh transistor T7 may be referred to as a light emitting transistor. When a signal of the light emitting signal line EM is an active level signal, the seventh transistor T7 causes the light emitting device to emit light by forming a drive current path between the first power supply line VDD and a second power supply line VSS.

In an exemplary implementation, a length of a channel region of an active layer of the sixth transistor is larger than a length of a channel region of an active layer of any one of the first transistor to the fifth transistor and the seventh transistor. A width of the channel region of the active layer of the sixth transistor is larger than a width of the channel region of the active layer of any one of the first transistor to the fifth transistor and the seventh transistor. A width-length ratio of the channel region of the active layer of the sixth transistor is smaller than a width-length ratio of the channel region of the active layer of any one of the first transistor to the fifth transistor and the seventh transistor.

An exemplary structure of the node control sub-circuit, the drive sub-circuit and the light emitting control sub-circuit is shown in FIG. 5. Those skilled in the art can easily understand that implementations of the node control sub-circuit, the drive sub-circuit and the light emitting control sub-circuit are not limited thereto.

Transistors may be divided into N-type transistors and P-type transistors according to their characteristics. When a transistor is a P-type transistor, its turn-on voltage is a low-level voltage (e.g., 0V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, for the first transistor T1 to the seventh transistor T7, low temperature poly silicon thin film transistors may be used, or oxide thin film transistors may be used, or both a low temperature poly silicon thin film transistor and an oxide thin film transistor may be used. An active layer of a low temperature poly silicon thin film transistor may be made of Low Temperature Poly silicon (LTPS for short), and an active layer of an oxide thin film transistor may be made of an oxide semiconductor (Oxide). Low temperature poly-silicon thin film transistors have advantages such as high migration rate and fast charging, and oxide thin film transistors have advantages such as low leakage current. Low temperature poly-silicon thin film transistors and oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency driving can be achieved, power consumption can be decreased, and display quality can be improved.

In an exemplary implementation, the first transistor T1, the fourth transistor T4 and the fifth transistor T5 may be oxide transistors.

In an exemplary implementation, the first transistor T1, the fourth transistor T4, and the fifth transistor T5 may be N-type transistors, and the second transistor T2, the third transistor T3, the sixth transistor T6, and the seventh transistor T7 may be P-type transistors.

In an exemplary implementation, a width-length ratio of the channel regions of the active layers of the first transistor T1 to the fifth transistor T5 may be 2.5/3.

In an exemplary implementation, a width-length ratio of the channel region of the active layer of the sixth transistor (drive transistor) T6 may be 3.5/20.

In an exemplary implementation, the width-length ratio of the channel region of the active layer of the seventh transistor T7 may be 2.0/2.5.

In an exemplary implementation, the signal of the first scan signal line Gate1 and the signal of the second scan signal line Gate2 may be mutually inverted signals.

In an exemplary implementation, when r signal of the third scan signal line Gate3 is an active level signal, the signals of the first scan signal line Gate1 and the second scan signal line Gate2 are active level signals, and the signals of the fourth scan signal line Gate4 and the light emitting signal line EM are inactive level signals.

In an exemplary implementation, when the signal of the fourth scan signal line Gate4 is an active level signal, the signals of the first scan signal line Gate1, the second scan signal line Gate2, the third scan signal line Gate3, and the light emitting signal line EM are inactive level signals.

In an exemplary implementation, when the signal of the light emitting signal line EM is an active level signal, the signals of the first scan signal line Gate1, the second scan signal line Gate2, the third scan signal line Gate3, and the fourth scan signal line Gate4 are inactive level signals.

In an exemplary implementation, a duration for which a signal of any one of the first scan signal lines Gate1 and the second scan signal lines Gate2 is an active level signal is longer than a duration for which a signal of any one of the third scan signal lines Gate3 and the fourth scan signal lines Gate4 is an active level signal.

In an exemplary implementation, the signal of the first initial signal line INIT1 and the signal of the second initial signal line INIT2 may be the same signal, and a voltage value of the signal of the first initial signal line INIT1 is smaller than a voltage value of the signal of the third initial signal line INIT3.

In an exemplary implementation, the first initial signal line INIT1 and the second initial signal line INIT2 may be the same signal line or may be different signal lines that transmit the same signal, which are not limited in the present disclosure.

In an exemplary implementation, a voltage value of the signal of the first initial signal line INIT1 may be about −2.8 volts (V) to −3.2 volts (V), and for example, the voltage value of the signal of the first initial signal line INIT1 may be about −3 volts (V).

In an exemplary implementation, a voltage value of the signal of the third initial signal line INIT3 may be about 5 volts (V) to 7 volts (V), and for example, the voltage value of the signal of the third initial signal line INIT3 may be about 6 volts (V).

In an exemplary implementation, a voltage value of the signal of the second initial signal line INIT2 may be greater than a voltage value of the signal of the second power supply line VSS. For example, the voltage value of the signal of the second initial signal line INIT2 may be slightly larger than a voltage value of the signal of the second power supply line VSS, and when the voltage value of the signal of the second initial signal line INIT2 is larger than the voltage value of the signal of the second power supply line VSS, it may ensure that the light emitting device does not emit light when the second node N2 (also the anode of the light emitting device) is reset, thus improving a display effect.

FIG. 6 is a working timing diagram of a pixel drive circuit. Exemplary embodiments of the present disclosure will be described below with reference to a working process of a pixel drive circuit illustrated in FIG. 5. The pixel drive circuit in FIG. 5 includes seven transistors (a first transistor T1 to a seventh transistor T7) and two capacitors (a first capacitor C1 and a second capacitor C2). Herein, the first transistor T1, the fourth transistor T4 and the fifth transistor T5 are N-type transistors, and the second transistor T2, the third transistor T3, the sixth transistor T6 and the seventh transistor T7 are P-type transistors.

In an exemplary implementation, the working process of the pixel drive circuit may include following stages.

In a first stage P1, referred to as an initialization stage, signals of the first scan signal line Gate1 and the light emitting signal line EM are high-level signals, and signals of the second scan signal line Gate2, the third scan signal line Gate3 and the fourth scan signal line Gate4 are low-level signals. The signal of the first scan signal line Gate1 is a high-level signal, so that the first transistor T1 and the fourth transistor T4 are turned on, and a first initial signal of the first initial signal line INIT1 is written to the first node N1 through the turned-on first transistor T1, so as to initialize (reset) the first node N1, empty a pre-stored voltage in the first node N1 and complete the initialization. The signal of the second scan signal line Gate2 is a low-level signal, so that the second transistor T2 is turned on, and a second initial signal of the second initial signal line INIT2 is written to the second node N2 (also the anode of the light emitting device L) through the turned-on second transistor T2, so as to initialize (reset) the second node N2 (the anode of the light emitting element L), empty a pre-stored voltage in the second node N2 and complete the initialization. The signal of the third scan signal line Gate3 is a low-level signal, the third transistor T3 is turned on, so that a third initial signal of the third initial signal line INIT3 is written to the third node N3 and the fourth node N4 through the turned-on third transistor T3 and the turned-on fourth transistor T4, so as to initialize (reset) the third node N3 and the fourth node N4, empty pre-stored voltages in the third node N3 and the fourth node N4, and complete the initialization. At this time, a difference between the voltage values of signals of the first node N1 and the third node N3 is smaller than a threshold voltage of the sixth transistor T6, and the sixth transistor T6 is turned on. The signal of the fourth scan signal line Gate4 is a low-level signal, the fifth transistor T5 is turned off, the signal of the light emitting signal line EM is a high-level signal, and the seventh transistor T7 is turned off. At this stage, since a voltage value of the second initial signal of the second initial signal line INIT2 is slightly smaller than a voltage value of a signal of the second power supply line VSS, the light emitting device L does not emit light.

In a second stage P2, referred to as a threshold compensation stage, signals of the first scan signal line Gate1, the third scan signal line Gate3 and the light emitting signal line EM are high-level signals, and signals of the second scan signal line Gate2 and the fourth scan signal line Gate4 are low-level signals. The signal of the first scan signal line Gate1 is a high-level signal, so that the first transistor T1 and the fourth transistor T4 are continuously turned on, and the first initial signal of the first initial signal line INIT1 is written to the first node N1 through the turned-on first transistor T1, so as to continue to initialize (reset) the first node N1, empty the pre-stored voltage inside the first node N1 and complete the initialization. The signal of the second scan signal line Gate2 is a low-level signal, so that the second transistor T2 is turned on, the second initial signal of the second initial signal line INIT2 is written to the second node N2 (also the anode of the light emitting device L) through the turned-on second transistor T2, so as to initialize (reset) the second initial signal of the second initial signal line INIT2, empty the pre-stored voltage in the second node N2, and complete the initialization. The fourth node N4 is charged by the second initial signal of the second initial signal line INIT2 through the turned-on second transistor T2, the second node N2, the sixth transistor T6, the third node N3 and the turned-on fourth transistor T4 until a voltage value of the signal of the fourth node N4 meets V4=Vinit1−Vth, wherein Vinit1 is a voltage value of the first initial signal. The signal of the third scan signal line Gate3 is a high-level signal, the third transistor T3 is turned off, the signal of the fourth scan signal line Gate4 is a low-level signal, the fifth transistor T5 is turned off, the signal of the light emitting signal line EM is a high-level signal, and the seventh transistor T7 is turned off. At this stage, since the voltage value of the second initial signal of the second initial signal line INIT2 is slightly smaller than the voltage value of the signal of the second power supply line VSS, the light emitting device L does not emit light.

In a third stage P3, referred to as a data write stage, signals of the second scan signal line Gate2, the third scan signal line Gate3, the fourth scan signal line Gate4 and the light emitting signal line EM are high-level signals, and the signal of the first scan signal line Gate1 is a low-level signal. The data signal line Data outputs a data signal. The signal of the fourth scan signal line Gate4 is a high-level signal, so that the fifth transistor T5 is turned on, and the data signal of the data signal line Data is written to the fourth node N4 through the turned-on fifth transistor T5. At this time, the voltage value V4 of the signal of the fourth node jumps and meets V4=Vdata, wherein Vdata is a voltage value of the data signal. Under action of the second capacitor C2, the voltage value V1 of the signal of the first node N1 jumps and meets V1=Vdata+Vth. The signal of the first scan signal line Gate1 is a low-level signal, the first transistor T1 and the fourth transistor T4 are turned off, the signal of the second scan signal line Gate2 is a high-level signal, the second transistor T2 is turned off, the signal of the third scan signal line Gate3 is a high-level signal, the third transistor T3 is turned off, the signal of the light emitting signal line EM is a high-level signal, and the seventh transistor T7 is turned off. The light emitting device L does not emit light in this stage.

In a first stage P4, referred to as a light emitting stage, signals of the second scan signal line Gate2 and the third scan signal line Gate3 are high-level signals, and signals of the first scan signal line Gate1, the fourth scan signal line Gate4 and the light emitting signal line EM are low-level signals. When the signal of the light emitting signal line EM is a low-level signal, the seventh transistor T7 is turned on, and a power supply signal outputted from the first power supply line VDD provides a driving voltage to the second node N2 (the first electrode of the light emitting device L) through the turned-on seventh transistor T7, the third node N3 and the turned-on fifth transistor T6 to drive the light emitting device L to emit light. The signal of the first scan signal line Gate1 is a low-level signal, and the first transistor T1 and the fourth transistor T4 are turned off. The signal of the second scan signal line Gate2 is a high-level signal, the second transistor T2 is turned off. The signal of the third scan signal line Gate3 is a high-level signal, the third transistor T3 is turned off. The signal of the fourth scan signal line Gate4 is a low-level signal, and the fifth transistor T5 is turned off.

In a drive process of the pixel drive circuit, a drive current flowing through the sixth transistor T6 (the drive transistor) is determined by a voltage difference between a gate electrode and the first electrode of the sixth transistor T6. Since the voltage of the first node N1 is Vdata+Vth, a voltage value of the signal of the third node N3 is V3=Vdd, wherein Vdd is a voltage value of the signal of the first power supply line, the drive current of the sixth transistor T6 is:

$$I = K * {( Vgs - Vth )}^{2} = K * {( Vdata + Vth - Vdd - Vth )}^{2} = K * {( Vdata - Vdd )}^{2}$$

Herein, I is the drive current flowing through the sixth transistor T6, that is, a drive current driving the light emitting device L, K is a constant, Vgs is the voltage difference between the gate electrode and the first electrode of the sixth transistor T6, and Vth is a threshold voltage of the sixth transistor T6.

It can be seen from a derivation result of the above current formula that in the light emitting stage, the drive current of the sixth transistor T6 is not affected by the threshold voltage of the sixth transistor T6. Therefore, influence of the threshold voltage of the sixth transistor T6 on the drive current is eliminated, which can ensure uniformity of display brightness of the display product, and improve an overall display effect of the display product.

In the present disclosure, in the second stage, i.e. the threshold compensation stage, the signal of the fourth node N4 is compensated by the signal of the second initial signal line INIT2, so that compensation time of the pixel drive circuit is prolonged, charging time of the pixel drive circuit is increased, and the reliability of the pixel drive circuit is improved.

An embodiment of the present disclosure further provides a display substrate, which includes a base substrate and a plurality of sub-pixels arranged on the base substrate, and at least one sub-pixel includes a pixel drive circuit and a light emitting device driven by the pixel drive circuit.

The pixel drive circuit is a pixel drive circuit according to any one of the foregoing embodiments, and an implementation principle and implementation effects are similar, which will not be repeated here.

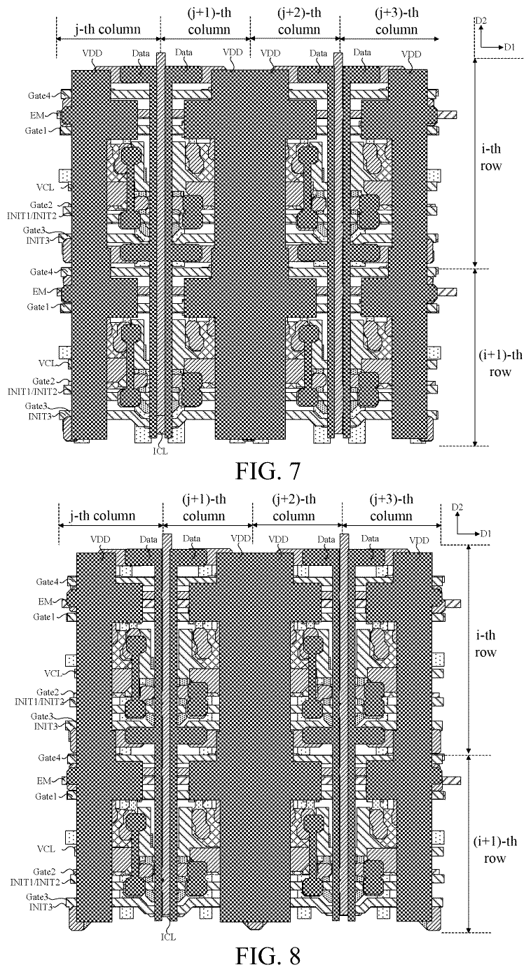

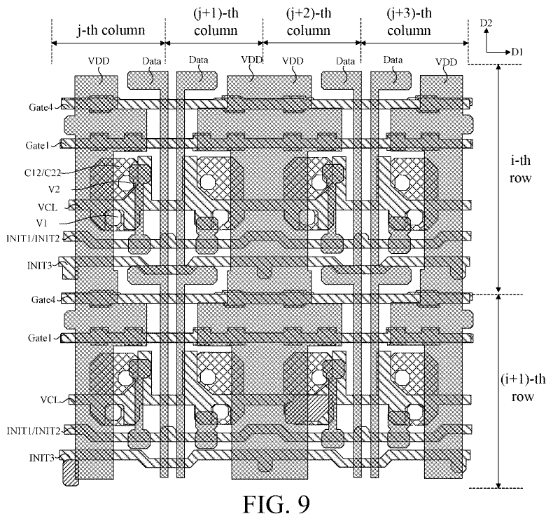

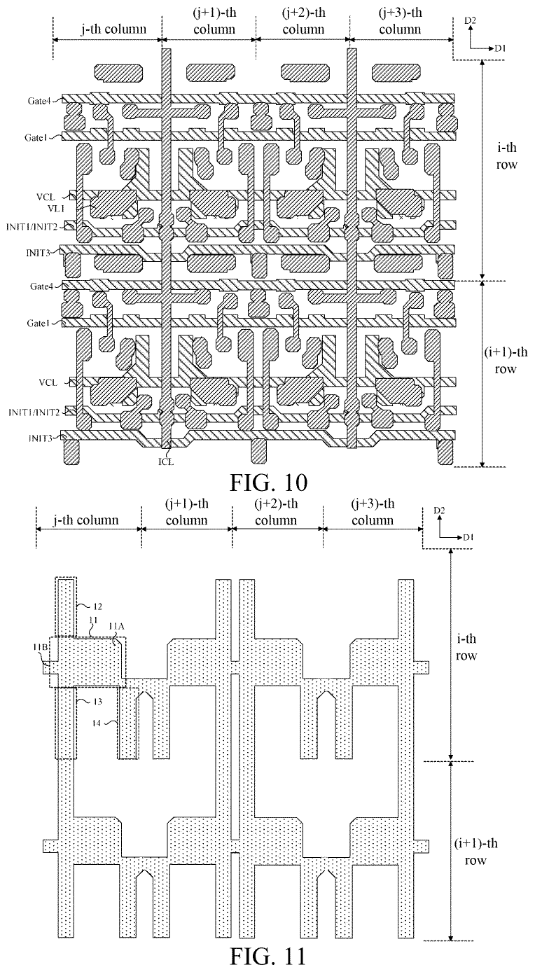

FIG. 7 is a first schematic structural diagram of a display substrate according to an embodiment of the present disclosure, FIG. 8 is a second schematic structural diagram of a display substrate according to an embodiment of the present disclosure, FIG. 9 is a first schematic diagram of a partial film layer of a display substrate, and FIG. 10 is a second schematic diagram of a partial film layer of a display substrate. As shown in FIGS. 7 to 10, the display substrate may include a base substrate, and a drive circuit layer and a light emitting structure layer provided sequentially on the base substrate. The drive circuit layer includes a plurality of pixel drive circuits, a plurality of light emitting signal lines EM, a plurality of first initial signal lines INIT1, a plurality of second initial signal lines INIT2, a plurality of third initial signal lines, a plurality of first scan signal lines Gate1, a plurality of second scan signal lines Gate2, a plurality of third scan signal lines Gate3, a plurality of fourth scan signal lines Gate4, a plurality of first power supply lines VDD and a plurality of data signal lines Data. The light emitting structure layer includes a light emitting device.

In an exemplary implementation, as shown in FIGS. 7 to 10, any one of the light emitting signal lines EM, the first initial signal lines INIT1, the second initial signal lines INIT2, the third initial signal line, the first scan signal line Gate1, the second scan signal line Gate2, the third scan signal line Gate3, and the fourth scan signal line Gate4 extends at least partially along a first direction D1, and any one of the first power supply lines VDD and the data signal lines Data extends at least partially along a second direction D2, wherein the first direction D1 intersects with the second direction D2.

In an exemplary implementation, the display substrate may further include an encapsulation structure layer arranged on a side of the light emitting structure layer away from the base substrate. The display substrate may include another film layer such as a touch structure layer, which is not limited here in the present disclosure.

In an exemplary implementation, on a plane parallel to the display substrate, the display substrate may include a plurality of sub-pixels, at least one of which may include a pixel drive circuit and a light emitting device. The pixel drive circuit is configured to output a corresponding current to a light emitting device connected thereto so that the light emitting device emits light of a corresponding brightness.

In an exemplary implementation, the plurality of sub-pixels may include a plurality of pixel rows and a plurality of pixel columns. A plurality of sub-pixels sequentially arranged along a horizontal direction are referred to as a pixel row, and a plurality of sub-pixels sequentially arranged along a vertical direction are referred to as a pixel column. The plurality of pixel rows and the plurality of pixel columns constitute a pixel array.

In an exemplary implementation, a plurality of sub-pixels constitute a pixel unit, and the pixel unit may include a first sub-pixel, a second sub-pixel, and a third sub-pixel, or may include a first sub-pixel, a second sub-pixel, a third sub-pixel, and a fourth sub-pixel.

In an exemplary implementation, when the pixel unit includes a first sub-pixel, a second sub-pixel, and a third sub-pixel, the first sub-pixel may be a red sub-pixel (R) that emits red light, the second sub-pixel may be a blue sub-pixel (B) that emits blue light, the third sub-pixel P3 may be a green sub-pixel (G) that emits green light, and a shape of the three sub-pixels may be triangular, rectangular, diamond, pentagonal, hexagonal, etc., which is not limited here in the present disclosure. In a direction of pixel rows, the first sub-pixel, the second sub-pixel, and the third sub-pixel may be sequentially arranged in an aligned manner, and in a direction of the pixel columns, the first sub-pixel, the second sub-pixel, and the third sub-pixel may be sequentially arranged in a misaligned manner to form a layout of the sub-pixels in a delta-shaped arrangement. For example, a first sub-pixel in an odd-numbered row may be located between its adjacent second sub-pixel and third sub-pixel in even-numbered rows, or a first sub-pixel in an even-numbered row may be located between its adjacent second sub-pixel and third sub-pixel in odd-numbered rows. As another example, a second sub-pixel in an odd-numbered row may be located between its adjacent first sub-pixel and third sub-pixel in even-numbered rows, or a second sub-pixel in an even-numbered row may be located between its adjacent first sub-pixel and third sub-pixel in odd-numbered rows. As another example, a third sub-pixel in an odd-numbered row may be located between its adjacent first sub-pixel and second sub-pixel in even-numbered rows, or a third sub-pixel in an even-numbered row may be located between its adjacent first sub-pixel and second sub-pixel in odd-numbered rows.

In an exemplary implementation, when the pixel unit includes a first sub-pixel, a second sub-pixel, a third sub-pixel, and a fourth sub-pixel, the first sub-pixel may be a red sub-pixel (R) emitting red light, the second sub-pixel may be a blue sub-pixel (B) emitting blue light, the third sub-pixel and the fourth sub-pixel may each be a green sub-pixel (G) emitting green light, and a shape of the three sub-pixels may be triangular, rectangular, diamond, pentagonal, hexagonal, etc., which is not limited here in the present disclosure. In an exemplary implementation, the four sub-pixels may be arranged side by side horizontally, side by side vertically, or in a manner of forming a square, which is not limited here in the present disclosure. The four sub-pixels may be arranged in a manner of forming a square to form a GGRB pixel arrangement. In another exemplary implementation, the four sub-pixels may be arranged in a manner of forming a diamond to form an RGGB pixel arrangement.

In an exemplary implementation, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer, and it may be ensured that external water vapor cannot enter the light emitting structure layer.

In an exemplary implementation, the base substrate may be a rigid base substrate or a flexible base substrate, wherein the rigid base substrate may be, but is not limited to, one or more of glass and conductive foil. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the light emitting structure layer includes an anode layer, a pixel definition layer, an organic structure layer, and a cathode layer that are sequentially stacked on the base substrate. The anode layer includes an anode, the organic structure layer includes an organic light emitting layer, and the cathode layer includes a cathode.

In an exemplary implementation, as shown in FIGS. 7 to 10, the drive circuit layer further includes a plurality of power supply connection lines VCL extending at least partially along the first direction. At least one of the power supply connection lines VCL is connected to a pixel drive circuit and at least one of the first power supply lines VDD respectively. In the present disclosure, a plurality of power supply connection lines VCL extending along the first direction and a plurality of first power supply lines extending along the second direction form a mesh structure, which may ensure that a power supply signal of each pixel drive circuit is the same, and may improve display uniformity of the display substrate.

In an exemplary implementation, the drive circuit layer may further include a first connection electrode. The first connection electrode is connected to a pixel drive circuit, a power supply connection line VCL and a first power supply line VDD respectively. An orthographic projection of the first connection electrode on the base substrate is at least partially overlapped with orthographic projections of the power supply connection line VCL and the first power supply line VDD on the base substrate.

In an exemplary implementation, as shown in FIGS. 7 and 8, the first initial signal lines INIT1 and the second initial signal lines INIT2 are the same signal lines.

In an exemplary implementation, as shown in FIGS. 7 and 8, the drive circuit layer may further include a plurality of initial connection lines ICL extending at least partially along the second direction D2. At least one of the initial connection lines ICL is connected to a pixel drive circuit and at least one of the first initial signal lines INIT1 respectively. In the present disclosure, a plurality of first initial signal lines INIT1 extending along the first direction and a plurality of initial connection lines ICL extending along the second direction form a mesh structure, which may reduce an influence of a difference of initial signals of first initial signal lines connected to different pixel drive circuits on the low gray-scales caused by resistance differences of the first initial signal lines, and may improve the display uniformity of the display substrate.

In an exemplary implementation, as shown in FIGS. 7 and 8, an orthographic projection of an initial connection line ICL on the base substrate may be located between orthographic projections of data signal lines Data connected to two adjacent columns of sub-pixels connected by the initial connection line ICL on the base substrate.

In an exemplary implementation, a first scan signal line Gate1 includes a first sub-signal line and a second sub-signal line electrically connected to each other. For example, the first sub-signal line and the second sub-signal line may be arranged in different layers and may be electrically connected at a periphery of a display region. An orthographic projection of the first sub-signal line on the base substrate is at least partially overlapped with an orthographic projection of the second sub-signal line on the base substrate.

In an exemplary implementation, a fourth scan signal line Gate4 includes a third sub-signal line and a fourth sub-signal line arranged in different layers and connected to each other. For example, the third sub-signal line and the fourth sub-signal line may be arranged in different layers and electrically connected at the periphery of the display region. An orthographic projection of the third sub-signal line on the base substrate is at least partially overlapped with an orthographic projection of the fourth sub-signal line on the base substrate.

In an exemplary implementation, the pixel drive circuit includes a first transistor to a seventh transistor, and a first capacitor and a second capacitor. The first capacitor and the second capacitor each includes a first plate and a second plate respectively. The drive circuit layer includes a first semiconductor layer, a first conductive layer, a second conductive layer, a second semiconductor layer, a third conductive layer, a fourth conductive layer and a fifth conductive layer which are sequentially arranged on the base substrate.

The first semiconductor layer at least includes: an active layer of the second transistor, an active layer of the third transistor, an active layer of the sixth transistor and an active layer of the seventh transistor in at least one pixel.

The first conductive layer at least includes: a light emitting signal line EM, a second scan signal line Gate2, a third scan signal line Gate3 and a first plate of the first capacitor, a first plate of the second capacitor, a gate electrode of the second transistor, a gate electrode of the third transistor, a control electrode of the sixth transistor and a gate electrode of the seventh transistor in at least one sub-pixel.

The second conductive layer at least includes: a first sub-signal line of the first scan signal line Gate1, a third sub-signal line of the fourth scan signal line Gate4, a second plate of the first capacitor and a second plate of the second capacitor in at least one sub-pixel.

The second semiconductor layer at least includes: an active layer of the first transistor, an active layer of the fourth transistor and an active layer of the fifth transistor in at least one sub-pixel.

The third conductive layer at least includes: a second sub-signal line of the first scan signal line Gate1, a fourth sub-signal line of the fourth scan signal line Gate4, a power supply connection line VCL, a first initial signal line INIT1, a second initial signal line INIT2 and a third initial signal line.

The fourth conductive layer at least includes: an initial connection line ICL, and a first connection electrode and first electrodes and second electrodes of the first transistor to the seventh transistor in at least one sub-pixel.

The fifth conductive layer at least includes: a first power supply line VDD and a data signal line Data.

In the present disclosure, a signal line transmitting a power supply signal includes a power supply connection line located in the third conductive layer and a first power supply line located in the fifth conductive layer. A signal line transmitting a data signal includes a data signal line of the fifth conductive layer. The second plate of the first capacitor and the second plate of the second capacitor are located in the second conductive layer. The signal line transmitting the power supply signal includes the power supply connection line located in the third conductive layer, which may shield a parasitic capacitance between the second plate of the first capacitor and the second plate of the second capacitor located in the second conductive layer, and the data signal line of the fifth conductive layer (also a parasitic capacitance between the signal of the gate electrode of the sixth transistor and the data signal), and may avoid crosstalk between signals, thus improving reliability of the display substrate.

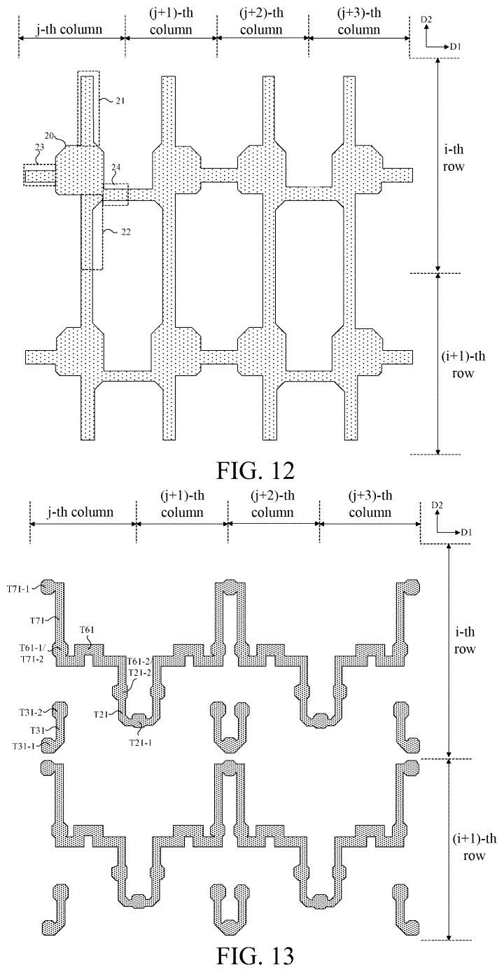

In an exemplary implementation, FIG. 11 is a schematic diagram of a pattern of a light shielding layer of the display substrate provided in FIG. 7, and FIG. 12 is a schematic diagram of a pattern of a light shielding layer of the display substrate provided in FIG. 8. As shown in FIGS. 11 and 12, the drive circuit layer may further include a light shielding layer arranged between the base substrate and the first semiconductor layer. The light shielding layer at least includes a light shielding structure located in at least one sub-pixel, and light shielding structures of adjacent sub-pixels are connected to each other.

In an exemplary implementation, an orthographic projection of the light shielding structure on the base substrate may be at least partially overlapped with an orthographic projection of the gate electrode of the sixth transistor on the base substrate. For example, the orthographic projection of the light shielding structure on the base substrate may cover the orthographic projection of the gate electrode of the sixth transistor on the base substrate, and the orthographic projection of the light shielding structure on the base substrate covering the orthographic projection of the gate electrode of the sixth transistor (also the drive transistor) on the base substrate may improve a service life of the drive transistor and the reliability of the display substrate.

In an exemplary implementation, as shown in FIG. 11, the light shielding structure may include a first light shielding portion 11, a second light shielding portion 12, a third light shielding portion 13 and a fourth light shielding portion 14. Herein, an orthographic projection of the first light shielding portion 11 on the base substrate is at least partially overlapped with an orthographic projection of the active layer of the sixth transistor on the base substrate. An orthographic projection of the second light shielding portion 12 on the base substrate is at least partially overlapped with an orthographic projection of the active layer of the seventh transistor on the base substrate. An orthographic projection of the third light shielding portion 13 on the base substrate is at least partially overlapped with an orthographic projection of the active layer of the third transistor on the base substrate. An orthographic projection of the fourth light shielding portion 14 on the base substrate is at least partially overlapped with an orthographic projection of the active layer of the second transistor on the base substrate.

In an exemplary implementation, as shown in FIG. 12, the light shielding structure may include a light shielding portion 20, a first light shielding connection portion 21, a second light shielding connection portion 22, a third light shielding connection portion 23 and a fourth light shielding connection portion 24. Herein, an orthographic projection of the light shielding portion 20 on the base substrate is at least partially overlapped with an orthographic projection of the active layer of the sixth transistor on the base substrate, and an orthographic projection of any of the first light shielding connection portion 21, the second light shielding connection portion 22, the third light shielding connection portion 23 and the fourth light shielding connection portion 24 on the base substrate is not overlapped with an orthographic projection of any of the active layers of the second transistor, the third transistor and the seventh transistor on the base substrate.

In an exemplary implementation, a light emitting signal line EM connected to a sub-pixel is located on a side of a first plate of a second capacitor of the sub-pixel away from a first plate of a first capacitor of the sub-pixel. A second scan signal line Gate2 connected to the sub-pixel is located on a side of the first plate of the first capacitor of the sub-pixel away from the first plate of the second capacitor of the sub-pixel. A third scan signal line Gate3 connected to the sub-pixel is located on a side of the second scan signal line Gate 2 connected to the sub-pixel away from the first plate of the first capacitor of the sub-pixel.

In an exemplary implementation, as shown in FIG. 9, the second plate C12 of the first capacitor and the second plate C22 of the second capacitor are connected to each other to form an integral structure, and are provided with a first via hole V1 and a second via hole V2. The first via hole exposes the first plate of the first capacitor, and the second via hole exposes the second plate of the second capacitor.

In an exemplary implementation, as shown in FIG. 9, the third sub-signal line of the fourth scan signal line Gate4 is located on a side of the first sub-signal line of the first scan signal line Gate1 away from the integral structure of the second plate C12 of the first capacitor and the second plate C22 of the second capacitor.

In an exemplary implementation, as shown in FIGS. 7 and 8, an orthographic projection of the first sub-signal line of the first scan signal line Gate1 connected to the sub-pixel on the base substrate is located between an orthographic projection of the light emitting signal line EM connected to the sub-pixel on the base substrate and an orthographic projection of the first plate of the second capacitor of the sub-pixel on the base substrate. An orthographic projection of the third sub-signal line of the fourth scan signal line Gate4 connected to the sub-pixel is located on a side of the orthographic projection of the light emitting signal line EM connected to the sub-pixel on the base substrate away from the orthographic projection of the first plate of the second capacitor of the sub-pixel on the base substrate.

In an exemplary implementation, as shown in FIGS. 7 and 8, the second sub-signal line of the first scan signal line Gate1 connected to the sub-pixel is located on a side of the fourth sub-signal line of the fourth scan signal line Gate4 connected to the sub-pixel. The power supply connection line VCL connected to the sub-pixel is located on a side of the second sub-signal line of the first scan signal line Gate1 connected to the sub-signal away from the fourth sub-signal line of the fourth scan signal line Gate4 connected to the sub-pixel. The first initial signal line INIT1 connected to the sub-pixel is located on a side of the power supply connection line VCL connected to the sub-pixel away from the second sub-signal line of the first scan signal line Gate1 connected to the sub-pixel. The third initial signal line connected to the sub-pixel is located on a side of the first initial signal line INIT1 connected to the sub-pixel away from the power supply connection line VCL connected to the sub-pixel.

In an exemplary implementation, as shown in FIGS. 7 and 8, an orthographic projection of the fourth sub-signal line of the fourth scan signal line Gate4 connected to the sub-pixel on the base substrate is located on a side of the orthographic projection of the light emitting signal line EM connected to the sub-pixel on the base substrate away from the orthographic projection of the first plate of the second capacitor of the sub-pixel on the base substrate.

In an exemplary implementation, as shown in FIGS. 7 and 8, an orthographic projection of the second sub-signal line of the first scan signal line Gate1 connected to the sub-pixel on the base substrate is located between the orthographic projection of the light emitting signal line EM connected to the sub-pixel on the base substrate and the orthographic projection of the first plate of the second capacitor of the sub-pixel on the base substrate.

In an exemplary implementation, as shown in FIGS. 7 and 8, an orthographic projection of the power supply connection line VCL connected to the sub-pixel on the base substrate is at least partially overlapped with an orthographic projection of the integral structure of the second plate of the first capacitor and the second plate of the second capacitor of the sub-pixel on the base substrate, and is located between the orthographic projection of the first sub-signal line of the first scan signal line Gate1 on the base substrate and an orthographic projection of the second scan signal line Gate2 on the base substrate.

In an exemplary implementation, as shown in FIGS. 7 and 8, an orthographic projection of the first initial signal line INIT1 connected to the sub-pixel on the base substrate is at least partially overlapped with the orthographic projection of the second scan signal line Gate2 connected to the sub-pixel on the base substrate, and is located between an orthographic projection of the first plate of the first capacitor of the sub-pixel on the base substrate and an orthographic projection of the third scan signal line Gate3 connected to the sub-pixel on the base substrate.

In an exemplary implementation, as shown in FIGS. 7 and 8, an orthographic projection of the third initial signal line INIT3 connected to the sub-pixel on the base substrate is at least partially overlapped with the orthographic projection of the third scan signal line Gate3 connected to the sub-pixel on the base substrate, and is located on a side of an orthographic projection of the second scan signal line Gate2 connected to the sub-pixel on the base substrate away from the orthographic projection of the first plate of the first capacitor of the sub-pixel on the base substrate.

In an exemplary implementation, the power supply connection line VCL includes a signal main body line, a first convex portion, a second convex portion and a third convex portion. The signal main body line extends along the first direction, the first convex portion is located on a side of the signal main body line close to the second sub-signal line of the first scan signal line Gate1, the second convex portion and the third convex portion are located on a side of the signal main body line away from the second sub-signal line of the first scan signal line Gate1, and the second convex portion and third convex portion are arranged along the first direction. Herein, orthographic projections of the second convex portion and the third convex portion on the base substrate are at least partially overlapped with an orthographic projection of the integral structure of the second plate of the first capacitor and the second plate of the second capacitor on the base substrate.

In an exemplary implementation, an orthographic projection of the first via hole on the base substrate is located between the orthographic projection of the second convex portion on the base substrate and the orthographic projection of the third convex portion on the base substrate.

In an exemplary implementation, as shown in FIGS. 7, 8 and 10, an orthographic projection of the first connection electrode VL1 on the base substrate is at least partially overlapped with the orthographic projections of the signal main body line, the second convex portion and the third convex portion of the power supply connection line VCL on the base substrate, and is not overlapped with the orthographic projection of the first convex portion of the power supply connection line VCL on the base substrate.

In an exemplary implementation, as shown in FIGS. 7 and 8, an orthographic projection of the first power supply line VDD on the base substrate is at least partially overlapped with orthographic projections of the integral structure of the second plate of the first capacitor and the second plate of the second capacitor, the first connection electrode, the signal main body portion and the second convex portion of the power supply connection line VCL on the base substrate.

In an exemplary implementation, as shown in FIGS. 7 and 8, the orthographic projection of the first power supply line VDD connected to the sub-pixel on the base substrate is located on a side of the data signal line Data connected to the sub-pixel away from the initial connection line ICL connected to the sub-pixel.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition. The coating may be any one or more of spray coating, spin coating, and inkjet printing. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are arranged in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B is located within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

A manufacturing process of the display substrate provided in FIG. 7 and FIG. 8 is explained below in terms of pixel drive circuits with two rows and fourth columns. A manufacturing process of a display substrate according to an exemplary implementation may include following steps.
(1) A pattern of a light shielding layer is formed on the base substrate, including sequentially depositing a first insulation thin film and a light shielding thin film on a substrate, and patterning the light shielding thin film by a patterning process to form a first insulation layer covering the substrate and a pattern of a light shielding layer located on the first insulation layer, as shown in FIG. 11 and FIG. 12.

In an exemplary implementation, as shown in FIG. 11 and FIG. 12, the light shielding layer may at least include a light shielding structure located in at least one sub-pixel.

In an exemplary implementation, as shown in FIG. 11 and FIG. 12, all the light shielding structures are connected to each other to form an integral structure. A light shielding structure of an adjacent sub-pixel located in a same row is arranged symmetrically with respect to a virtual straight line extending along the second direction D2, and light shielding structures of all sub-pixels located in a same column are the same.

In an exemplary implementation, as shown in FIG. 11, the light shielding structure in the display substrate provided in FIG. 7 includes a first light shielding portion 11 a second light shielding portion 12 a third light shielding portion 13 and a fourth light shielding portion 14. The first light shielding portion 11, the second light shielding portion 12, the third light shielding portion 13, and the fourth light shielding portion 14 are connected to each other to form an integral structure.

In the exemplary implementation, as shown in FIG. 11, the second light shielding portion 12 and the third light shielding portion 13 are arranged along the second direction D2, and the third light shielding portion 13 and the fourth light shielding portion 14 are arranged along the first direction D1. In the second direction D2, the second light shielding portion 12 of the sub-pixel may be located on a side of the first light shielding portion 11 close to sub-pixels in a previous row, and the third light shielding portion 13 and the fourth light shielding portion 14 of the sub-pixel may be located on a side of the first light shielding portion 11 close to sub-pixels in a next row. In the first direction D1, the fourth light shielding portion 14 of the sub-pixels may be located on a side of the third light shielding portion 13 close to sub-pixels in a next row or on a side of the third light shielding portion 13 close sub-pixels in a previous row.

In an exemplary implementation, as shown in FIG. 11, the first light shielding portion 11 may include a light shielding main body portion 11A and a light shielding connection portion 11B. The light shielding main body portion 11A and the light shielding connection portion 11B are connected to each other to form an integral structure.

In the exemplary implementation, as shown in FIG. 11, the light shielding main body portion 11A and the light shielding connection portion 11B are arranged in the first direction, and the light shielding main body portion 11A of the sub-pixel is located on the side of the light shielding connection portion 11B close to sub-pixels in a next row or on a side of the light shielding connection portion 11B close to sub-pixels in a previous row. When the fourth light shielding portion 14 may be located on a side of the third light shielding portion 13 close to sub-pixels in a next row, the light shielding main body portion 11A is located on a side of the light shielding connection portion 11B close to sub-pixels in a next row. When the fourth light shielding portion 14 may be located on a side of the third light shielding portion 13 close to sub-pixels in a previous row, the light shielding main body portion 11A is located on a side of the light shielding connection portion 11B close to sub-pixels in a previous row.

In an exemplary implementation, as shown in FIG. 11, a shape of the light shielding main body portion 11A may be a rectangular shape, and corners of the rectangular shape may be chamfered. A shape of the light shielding connection portion 11B may be a strip shape extending along the first direction D1.

In the exemplary implementation, as shown in FIG. 11, shapes of the second light shielding portion 12, the third light shielding portion 13 and the fourth light shielding portion 14 may be strip shapes extending along the second direction D2.

In an exemplary implementation, as shown in FIG. 11, the second shielding portion of the sub-pixel is connected to a third light shielding portion of a sub-pixel located in an previous row and a same column, and the third light shielding portion of the sub-pixel is connected to a second light shielding portion of a sub-pixel located in a next row and the same column. The light shielding connection portion of the first shielding portion of the sub-pixel is connected to a light shielding connection portion of a first light shielding portion of one adjacent sub-pixel in a same row, and the fourth light shielding portion of the sub-pixel is connected to a fourth light shielding portion of another adjacent sub-pixel in the same row.

In an exemplary implementation, as shown in FIG. 12, the light shielding structure of the display substrate provided in FIG. 8 may include a light shielding portion 20, a first light shielding connection portion 21, a second light shielding connection portion 22, a third light shielding connection portion 23, and a fourth light shielding connection portion 24. The light shielding portion 20, the first light shielding connection portion 21, the second light shielding connection portion 22, the third light shielding connection portion 23, and the fourth light shielding connection portion 24 are connected to each other to form an integral structure.

In an exemplary implementation, as shown in FIG. 12, the first light shielding connection portion 21 and the second light shielding connection portion 22 are arranged along a second direction D2. In the second direction D2, the first light shielding connection portion 21 of the sub-pixel may be located on a side of the light shielding portion 20 close to sub-pixels in an previous row, and the second light shielding connection portion 22 of the sub-pixel may be located on a side of the light shielding portion 20 close to sub-pixels in a next row. In a first direction D1, the third light shielding connection portion 23 and the fourth light shielding connection portion 24 of the sub-pixel are located on different sides of the light shielding portion 20. When the third light shielding connection portion 23 of the sub-pixel may be located on a side of the light shielding portion 20 close to the sub-pixels in the previous column, the fourth light shielding connection portion 24 of the sub-pixel may be located on a side of the light shielding portion 20 close to the sub-pixels in the next column. When the third light shielding connection portion 23 of the sub-pixel may be located on a side of the light shielding portion 20 close to the sub-pixels in the next column, the fourth light shielding connection portion 24 of the sub-pixel may be located on a side of the light shielding portion 20 close to the sub-pixels in the previous column.

In an exemplary implementation, as shown in FIG. 12, a shape of the light shielding portion 20 may be a rectangular shape, and corners of the rectangular shape may be chamfered.

In an exemplary implementation, as shown in FIG. 12, shapes of the first light shielding connection portion 21 and the second light shielding connection portion 22 may be strip shapes extending along the second direction D2. Shapes of the third light shielding connection portion 23 and the fourth light shielding connection portion 24 may be strip shapes extending along the first direction D1.

In an exemplary implementation, as shown in FIG. 12, the first light shielding connection portion of the sub-pixel is connected to a second light shielding connection portion of a sub-pixel located in an previous row and a same column, and the second light shielding connection portion of the sub-pixel is connected to a first light shielding connection portion of a sub-pixel located in a next row and the same column. The third light shielding connection portion of the sub-pixel is connected to a third light shielding connection portion of one adjacent sub-pixel in a same row, and the fourth light shielding connection portion of the sub-pixel is connected to a fourth light shielding connection portion of another adjacent sub-pixel in the same row.
(2) A pattern of a first semiconductor layer is formed. In an exemplary implementation, forming the pattern of the first semiconductor layer may include sequentially depositing a second insulation thin film and a first semiconductor thin film on the substrate, patterning the first semiconductor thin film by a patterning process to form a second insulation layer covering the light shielding layer and a pattern of a first semiconductor layer on the second insulation layer, as shown in FIGS. 13 to 15, wherein FIG. 13 is a schematic diagram of a pattern of a first semiconductor layer of the display substrate provided in FIG. 7 and FIG. 8, FIG. 14 is a schematic diagram of the display substrate provided in FIG. 7 after a pattern of a first semiconductor layer is formed, and FIG. 14 is a schematic diagram of the display substrate provided in FIG. 7 after a pattern of a first semiconductor layer is formed.

In an exemplary implementation, as shown in FIGS. 13 to 15, the pattern of the first semiconductor layer may at least include an active layer T21 of a second transistor, an active layer T31 of a third transistor, an active layer T61 of a sixth transistor, and an active layer T71 of a seventh transistor, which are located in at least one sub-pixel.

In an exemplary implementation, as shown in FIG. 14, in the display substrate provided in FIG. 7, an orthographic projection of the first light shielding portion on the base substrate is at least partially overlapped with an orthographic projection of the active layer T61 of the sixth transistor on the base substrate. An orthographic projection of the second light shielding portion on the base substrate is at least partially overlapped with an orthographic projection of the active layer T71 of the seventh transistor on the base substrate. An orthographic projection of the third light shielding portion on the base substrate is at least partially overlapped with an orthographic projection of the active layer T31 of the third transistor on the base substrate. An orthographic projection of the fourth light shielding portion on the base substrate is at least partially overlapped with an orthographic projection of the active layer T21 of the second transistor on the base substrate.

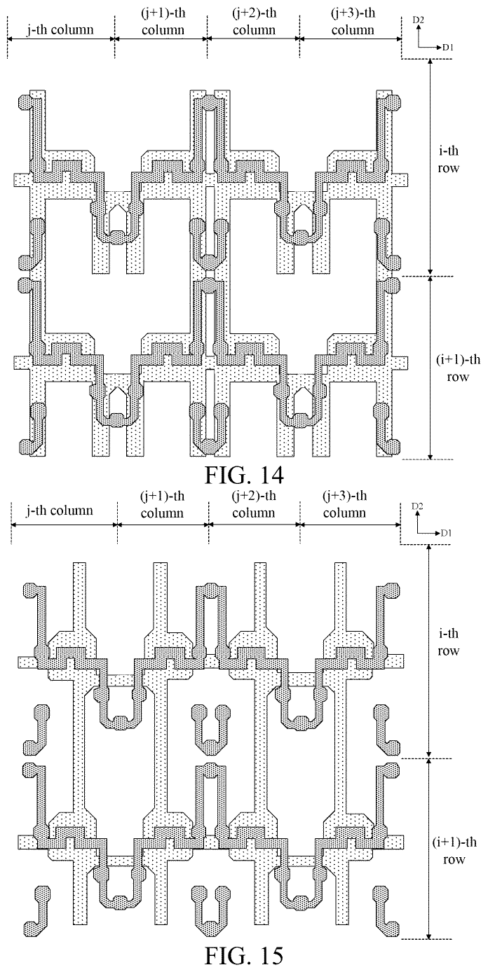

In an exemplary implementation, as shown in FIG. 15, in the display substrate provided in FIG. 8, an orthographic projection of the light shielding portion on the base substrate is at least partially overlapped with an orthographic projection of the active layer T61 of the sixth transistor on the base substrate. Orthographic projections of the first, second, third and fourth light shielding connection portions on the substrate are not overlapped with an orthographic projection of any of the active layer T21 of the second transistor, the active layer T31 of the third transistor and the active layer T71 of the seventh transistor on the substrate.

In an exemplary implementation, as shown in FIGS. 13 to 15, any one of the active layer T21 of the second transistor, the active layer T31 of the third transistor, the active layer T61 of the sixth transistor and the active layer T71 of the seventh transistor located in an adjacent sub-pixel in the same row is symmetrically arranged with respect to a virtual straight line extending along the second direction D2, and any one of the active layers T21 of the second transistors, the active layers T31 of the third transistors, the active layers T61 of the sixth transistors and the active layers T71 of the seventh transistors located in all sub-pixels in the same column is the same.

In an exemplary implementation, as shown in FIGS. 13 to 15, for the same sub-pixel, the active layer T21 of the second transistor, the active layer T61 of the sixth transistor, and the active layer T71 of the seventh transistor may be connected to each other to form an integral structure. The active layer T31 of the third transistor may be provided separately.

In an exemplary implementation, as shown in FIGS. 13 to 15, the active layer T31 of the third transistor of the sub-pixel is connected to the active layer T31 of the third transistor of one adjacent sub-pixel located in the same row, the active layer T71 of the seventh transistor of the sub-pixel is connected to the active layer T71 of the seventh transistor of one adjacent sub-pixel located in the same row, and the active layer T21 of the second transistor of the sub-pixel is connected to the active layer T21 of the second transistor of another adjacent sub-pixel located in the same row.

In the exemplary implementation, as shown in FIGS. 13 to 15, the active layer T31 of the third transistor and the active layer T71 of the seventh transistor are arranged along the second direction D2. In the first direction D1, the active layer T21 of the second transistor and the active layer T71 of the seventh transistor may be located on the same side of the active layer T61 of the sixth transistor of the sub-pixel, and the active layer T61 of the sixth transistor may be located on the other side of the active layer T61 of the sixth transistor of the sub-pixel. In the second direction D2, the active layer T71 of the seventh transistor may be located on a side of the active layer T61 of the sixth transistor of the sub-pixel close to sub-pixels in a previous row, and the active layer T21 of the second transistor and the active layer T31 of the third transistor may be located on a side of the active layer T61 of the sixth transistor of the sub-pixel close to sub-pixels in the next row.

In an exemplary implementation, as shown in FIGS. 13 to 15, the active layer T21 of the second transistor, the active layer T31 of the third transistor, and the active layer T71 of the seventh transistor may have an “I” shape. A shape of the active layer T61 of the sixth transistor may be an “Ω” shape.

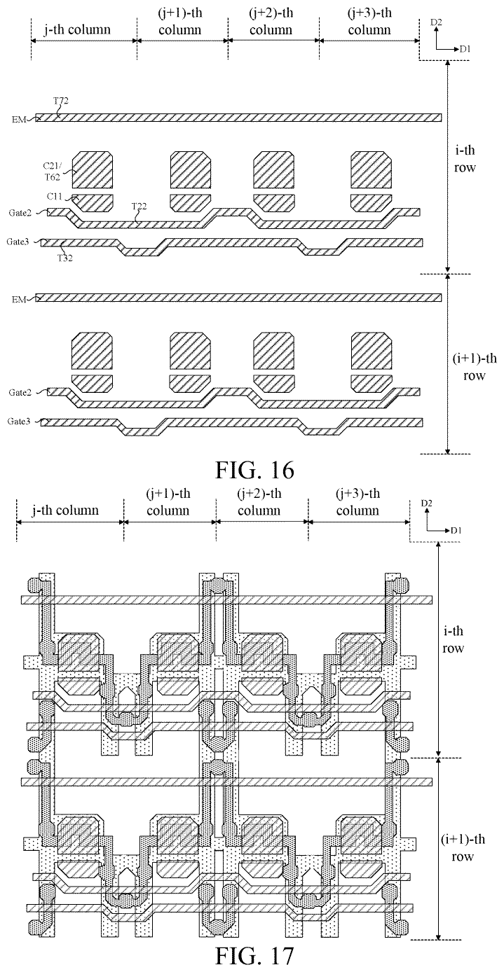

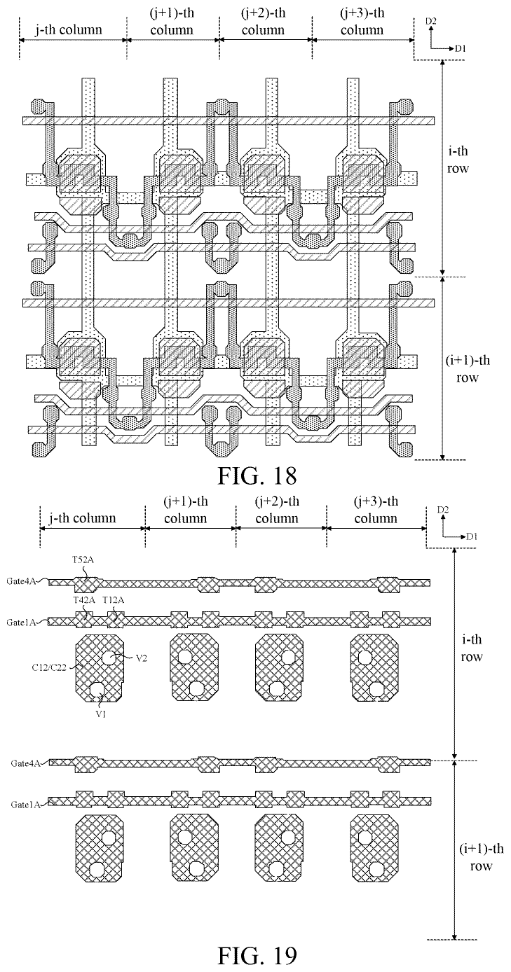

In an exemplary implementation, as shown in FIGS. 13 to 15, the active layer of the transistor may include a first region, a second region and a channel region between the first region and the second region. In an exemplary implementation, for sub-pixels, a second region T21-2 of the active layer T21 of the second transistor may serve as a second region T61-2 of the active layer T61 of the sixth transistor, and a first region T61-1 of the active layer T61 of the sixth transistor may serve as a second region T71-2 of the active layer T71 of the seventh transistor. A first region T31-1 and the second region T31-2 of the active layer T31 of the third transistor and a first region T71-1 of the active layer T71 of the seventh transistor may be separately provided. The first region T71-1 of the active layer T71 of the seventh transistor of the sub-pixel is the same region as the first region T71-1 of the active layer T71 of the seventh transistor of one adjacent sub-pixel located in the same row, and the first region T21-1 of the active layer T21 of the second transistor of the sub-pixel is the same region as the first region T21-1 of the active layer T21 of the second transistor of another adjacent sub-pixel located in the same row.
(3) A pattern of a first conductive layer is formed. In an exemplary implementation, forming the pattern of the first conductive layer may include: sequentially depositing a third insulation thin film and a first conductive thin film on the substrate on which the aforementioned patterns are formed, and the first conductive thin film is patterned through a patterning process to form a third insulation layer that covers the pattern of the first semiconductor layer and a pattern of a first conductive layer located in the third insulation layer, as shown in FIGS. 16 to 18, wherein FIG. 16 is a schematic diagram of a pattern of a first conductive layer of the display substrate provided in FIG. 7 and FIG. 8, FIG. 17 is a schematic diagram of the display substrate provided in FIG. 7 after a pattern of a first conductive layer is formed, and FIG. 18 is a schematic diagram of the display substrate provided in FIG. 8 after a pattern of a first conductive layer is formed. In an exemplary implementation, the first conductive layer may be referred to as a first gate metal (Gate1) layer.

In an exemplary implementation, as shown in FIGS. 16 to 18, the pattern of the first conductive layer may at least include a first plate C11 of the first capacitor, a first plate C21 of the second capacitor, a gate electrode T22 of the second transistor, a gate electrode T32 of the third transistor, a control electrode T62 of the sixth transistor, and a gate electrode T72 of the seventh transistor, which are located in at least one sub-pixel, and a light emitting signal line EM, a second scan signal line Gate2, and a third scan signal line Gate3, which extend at least partially along the first direction D1.

In an exemplary implementation, as shown in FIGS. 16 to 18, any one of the first plate of the first capacitor and the first plate of the second capacitor of an adjacent sub-pixel located in the same row is symmetrically arranged with respect to a virtual straight line extending along the second direction D2, and any one of the first plates of the first capacitors and the first plates of the second capacitors of all sub-pixels located in the same column is the same.

In an exemplary implementation, as shown in FIG. 16 to FIG. 18, the first plate C11 of the first capacitor and the first plate C21 of the second capacitor of a sub-pixel are arranged along the second direction D2, and the first plate C21 of the second capacitor of the sub-pixel may be located on a side of the first plate C11 of the first capacitor close to the previous row of sub-pixels.

In an exemplary implementation, as shown in FIGS. 16 to 18, a shape of the first plate C11 of the first capacitor may be a rectangular shape, corners of the rectangular shape may be provided with chamfers, and an orthographic projection of the first plate C11 of the first capacitor on the base substrate at least partially is overlapped with the orthographic projection of the active layer of the sixth transistor on the base substrate.

In an exemplary implementation, as shown in FIGS. 16 to 18, a shape of the first plate C21 of the second capacitor may be a rectangular shape, corners of the rectangular shape may be provided with chamfers, and an orthographic projection of the first plate C21 of the second capacitor on the base substrate at least partially is overlapped with the orthographic projection of the active layer of the sixth transistor on the base substrate. In an exemplary implementation, the first plate C21 of the second capacitor may simultaneously serve as a control electrode T62 of the sixth transistor.

In an exemplary implementation, an area of the first plate C21 of the second capacitor may be larger than an area of the first plate C11 of the first capacitor.

In an exemplary implementation, as shown in FIGS. 16 to 18, a shape of the second scan signal line Gate2 may be a line shape extending along the first direction D1, and the second scan signal line Gate2 connected to the sub-pixel may be located on a side of the first plate C11 of the first capacitor of the sub-pixel away from the first plate C21 of the second capacitor of the sub-pixel (also the gate electrode T62 of the sixth transistor). An overlapping region between the second scan signal line Gate2 and the active layer of the second transistor is used as the gate electrode of the second transistor.

In the exemplary implementation, as shown in FIGS. 16 to 18, a shape of the third scan signal line Gate3 may be a line shape extending along the first direction D1, and the third scan signal line Gate3 connected to a sub-pixel may be located on a side of the scan signal line Gate2 connected to the sub-pixel away from the first plate C11 of the first capacitor of the sub-pixel. An overlapping region between the third signal line Gate3 and the active layer of the third transistor is used as the gate electrode T32 of the third transistor.

In an exemplary implementation, as shown in FIGS. 16 to 18, a shape of the light emitting signal line EM may be a line shape extending along the first direction D1. The light emitting signal line EM connected to a sub-pixel may be located on a side of the first plate C21 of the second capacitor of the sub-pixel (also the gate electrode T62 of the sixth transistor) away from the first plate C11 of the first capacitor of the sub-pixel. An overlapping region between the light emitting signal line EM and the active layer of the seventh transistor is used as the gate electrode T72 of the seventh transistor.

In an exemplary implementation, the second scan signal line Gate2, the third scan signal line Gate3 and the light emitting signal line EM may be in a design of equal width, or may be in a design of non-equal widths, may be straight lines, or may be bend lines, which may not only facilitate the layout of the pixel structure, but also reduce the parasitic capacitance between the signal lines, which is not limited in the present disclosure.

In an exemplary implementation, after the pattern of the first conductive layer is formed, a conductive treatment may be performed on the first semiconductor layer by using the first conductive layer as a shield. The first semiconductor layer in a region shielded by the first conductive layer, forms channel regions of the second transistor, the third transistor, the sixth transistor and the seventh transistor T7, and the first semiconductor layer in a region not shielded by the first conductive layer, is made to be conductive, that is, first region and second region of any of the active layers of the first transistor, the second transistor, the sixth transistor and the seventh transistor are all made to be conductive.

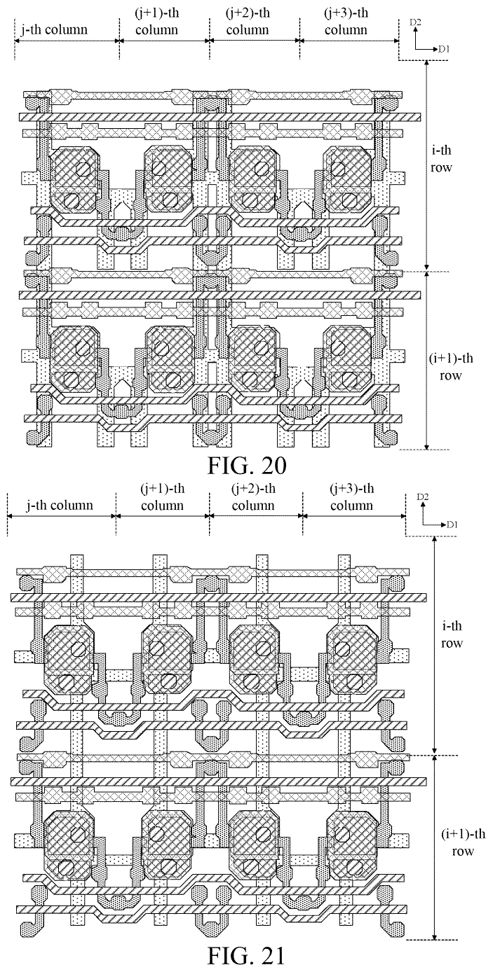

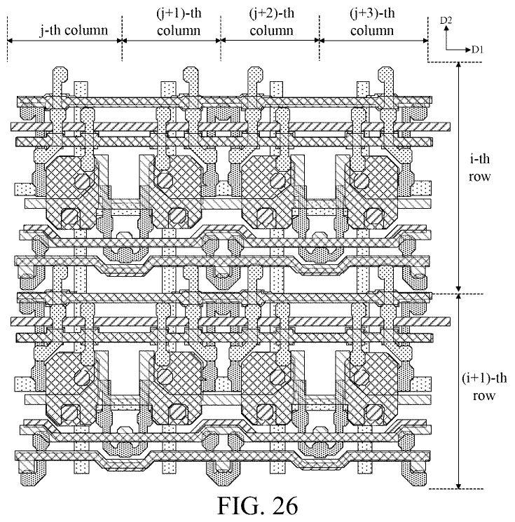

In an exemplary implementation, a gate electrode T22 of the second transistor is provided across an active layer of the second transistor, a gate electrode T32 of the third transistor is provided across the active layer of the third transistor, a gate electrode T62 of the sixth transistor is provided across the active layer of the sixth transistor, and a gate electrode T72 of the seventh transistor is provided across the active layer of the seventh transistor, that is to say, an extension direction of a gate electrode of at least one transistor is perpendicular to the extension direction of the active layer.
(4) Forming a pattern of a second conductive layer includes: depositing a fourth insulation thin film and a second conductive thin film sequentially on the substrate on which the aforementioned patterns are formed, patterning the fourth insulation thin film and the second conductive thin film by a patterning process to form a fourth insulation layer and a pattern of a second conductive layer located on the fourth insulation layer, as shown in FIGS. 19 to 21, wherein FIG. 19 is a schematic diagram of a pattern of a second conductive layer of the display substrate provided in FIGS. 7 and 8, FIG. 20 is a schematic diagram of the display substrate provided in FIG. 7 after a pattern of a second conductive layer is formed and FIG. 26 is a schematic diagram of the display substrate provided in FIG. 8 after a pattern of a second conductive layer is formed. In an exemplary implementation, the second conductive layer may be referred to as a second gate metal (GATE2) layer.

In an exemplary implementation, as shown in FIGS. 19 to 21, the second conductive layer may at least include a second plate C12 of the first capacitor and a second plate C22 of the second capacitor located in at least one sub-pixel, and a first sub-signal line Gate1A of the first scan signal line and a third sub-signal line Gate4A of the fourth scan signal line extending at least partially along the first direction D1.

In an exemplary implementation, any one of the second plate C12 of the first capacitor and the second plate C22 of the second capacitor of an adjacent sub-pixel located in the same row is symmetrically arranged with respect to a virtual straight line extending along the second direction D2, and any one of the second plate C12 of the first capacitor and the second plate C22 of the second capacitor of all sub-pixels located in the same column is the same.

In an exemplary implementation, as shown in FIGS. 19 to 21, the second plate C12 of the first capacitor and the second plate C22 of the second capacitor may be connected to each other to form an integral structure. A profile of the second plate C12 of the first capacitor (also the second plate C22 of the second capacitor) may be rectangular, corners of the rectangular shape may be chamfered, and an orthographic projection of the second plate C12 of the first capacitor (also the second plate C22 of the second capacitor) on the base substrate is at least partially overlapped orthographic projections of the first plate of the first capacitor and the first plate of the second capacitor on the base substrate.

In an exemplary implementation, as shown in FIGS. 19 to 21, the second plate C12 of the first capacitor (the second plate C22 of the second capacitor) is provided with a first via hole V1 and a second via hole V2, and shapes of the the first via hole V1 and the second via hole V2 may be rectangular shapes and are located in the middle of the second plate C12 of the first capacitor (the second plate C22 of the second capacitor). Herein, the first via hole V1 exposes the fourth insulation layer covering the first plate of the first capacitor, and an orthographic projection of the first plate of the first capacitor on the base substrate contains an orthographic projection of the first via hole on the base substrate. In an exemplary implementation, the first via hole V1 exposes the first plate of the first capacitor, so that a first connection electrode formed subsequently is connected to the first plate of the first capacitor. The second via hole V2 exposes the fourth insulation layer covering the first plate of the second capacitor, and an orthographic projection of the first plate of the second capacitor on the base substrate contains an orthographic projection of the second via hole on the base substrate. In an exemplary implementation, the second via hole V2 exposes the first plate of the second capacitor, so that a second electrode of the first transistor formed subsequently is connected to the first plate of the second capacitor.

In an exemplary implementation, as shown in FIGS. 19 to 21, a shape of the first sub-signal line Gate1A of the first scan signal line may be a line shape extending at least partially along the first direction D1, the first sub-signal line Gate1A of the first scan signal line connected to a sub-pixel may be located on a side of the second plate C12 of the first capacitor of the sub-pixel (the second plate C22 of the second capacitor) close the previous sub-pixel. An overlapping region between the first sub-signal line Gate1A of the first scan signal line connected to the sub-pixel and an active layer of the first transistor formed subsequently of the sub-pixel serves as the first gate electrode T12A of the first transistor, and an overlapping region between the first sub-signal line Gate1A of the first scan signal line connected to the sub-pixel and an active layer of the fourth transistor formed subsequently of the sub-pixel serves as the first gate electrode T42A of the fourth transistor.

In an exemplary implementation, as shown in FIGS. 19 to 21, an orthographic projection of the first sub-signal line Gate1A of the first scan signal line connected to a sub-pixel on the base substrate may be located between an orthographic projection of the light emitting signal line connected to the sub-pixel on the base substrate and an orthographic projection of the first plate of the second capacitor of the sub-pixel on the base substrate.

In an exemplary implementation, as shown in FIGS. 19 to 21, a shape of the third sub-signal line Gate4A of the fourth scan signal line may be a line shape extending at least partially along the first direction D1, the third sub-signal line Gate4A of the fourth scan signal line connected to a sub-pixel may be located on a side of the first sub-signal line Gate1A of the first scan signal line connected to the sub-pixel away from the second plate C12 (the second plate C22 of the second capacitor) of the first capacitor of the sub-pixel, and an overlapping region between the third sub-signal line Gate4A of the fourth scan signal line connected to the sub-pixel and an active layer of the fifth transistor formed subsequently of the sub-pixel serves as the first gate electrode T52A of the fifth transistor.

In an exemplary implementation, as shown in FIGS. 19 to 21, an orthographic projection of the third sub-signal line Gate4A of the fourth scan signal line connected to a sub-pixel on the base substrate may be located on a side of an orthographic projection of the light emitting signal line connected to the sub-pixel on the base substrate away from an orthographic projection of the first plate of the second capacitor of the sub-pixel on the base substrate.

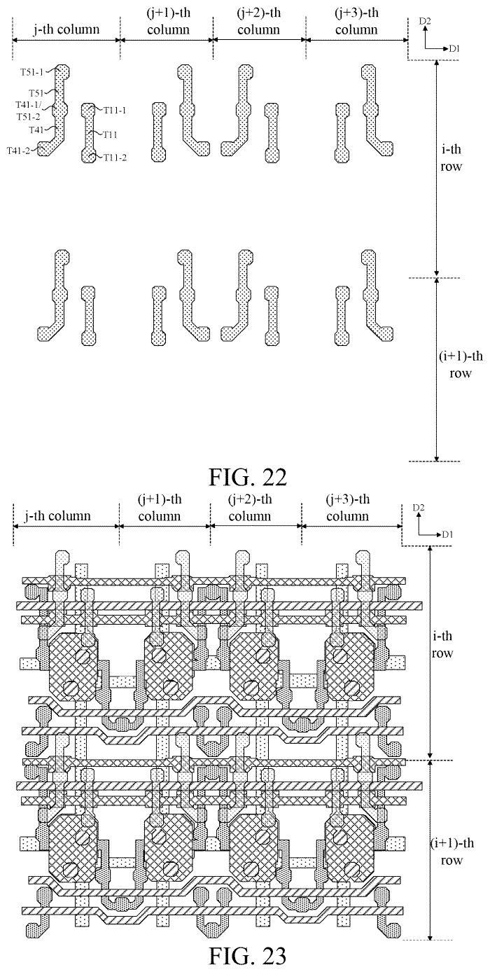

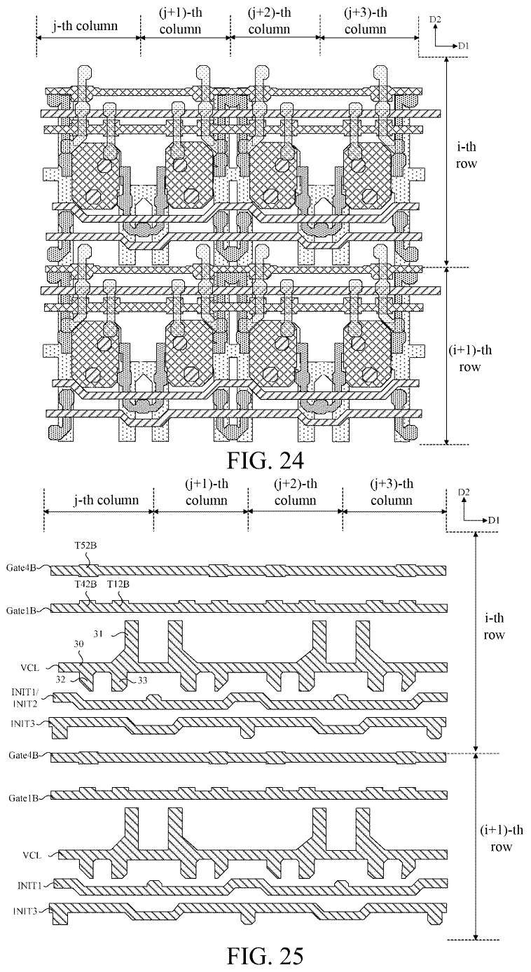

In an exemplary implementation, the first sub-signal line Gate1A of the first scan signal line and the third sub-signal line Gate4A of the fourth scan signal line may be in a design of equal width, or may be in a design of non-equal widths, may be straight lines, or may be bend lines, which may not only facilitate the layout of the pixel structure, but also reduce the parasitic capacitance between the signal lines, which is not limited here in the present disclosure.
(5) Forming a pattern of a second semiconductor layer includes: depositing a fifth insulation thin film and a second semiconductor thin film sequentially on the substrate on which the aforementioned patterns are formed on the base substrate, patterning the fifth insulation thin film and the second semiconductor thin film by a patterning process to form a fifth insulation layer and a pattern of a second semiconductor layer on the fifth insulation layer, as shown in FIGS. 22 to 24, wherein FIG. 22 is a schematic diagram of a pattern of a second semiconductor layer of the display substrate provided in FIGS. 7 and 8, FIG. 23 is a schematic diagram of the display substrate provided in FIG. 7 after a pattern of a second semiconductor layer is formed and FIG. 24 is a schematic diagram of the display substrate provided in FIG. 8 after a pattern of a second semiconductor layer is formed.

In an exemplary implementation, as shown in FIGS. 22 to 24, the second semiconductor layer may at least include an active layer T11 of the first transistor, an active layer T41 of the fourth transistor, and an active layer T51 of the fifth transistor located in at least one sub-pixel.

In an exemplary implementation, the active layer T41 of the fourth transistor and the active layer T51 of the fifth transistor are connected to each other to form an integral structure. The active layer T11 of the first transistor is provided separately.

In an exemplary implementation, as shown in FIGS. 22 to 24, any of an active layer T11 of the first transistor, an active layer T41 of the fourth transistor, and an active layer T51 of the fifth transistor located in an adjacent sub-pixel in the same row is symmetrically arranged with respect to a virtual straight line extending along the second direction D2, and any of active layers T11 of the first transistor, active layers T41 of the fourth transistor, and active layers T51 of the fifth transistor located in all sub-pixels in the same column are the same.

In an exemplary implementation, as shown in FIGS. 22 to 24, in the first direction D1, an active layer T11 of the first transistor of a sub-pixel may be located on a side of the active layer T41 of the fourth transistor close to the previous row of sub-pixels or close to the next row of sub-pixels. In the second direction D2, an active layer T51 of the fifth transistor of a sub-pixel may be located on a side of the active layer T41 of the fourth transistor of the sub-pixel close to the previous row of sub-pixels.

In an exemplary implementation, as shown in FIGS. 22 to 24, shapes of the active layer T11 of the first transistor and the active layer T51 of the fifth transistor may be in an “I” shape. A shape of the active layer T41 of the fourth transistor may be horizontally reversed in an “L” shape.

In an exemplary implementation, as shown in FIGS. 22 to 24, an orthographic projection of the active layer T11 of the first transistor of a sub-pixel on the base substrate is at least partially overlapped with orthographic projections of the first sub-signal line Gate1A of the first scan signal line connected to the sub-pixel, the light emitting signal line connected to the sub-pixel, and the second plate of the first capacitor of the sub-pixel (also the second plate of the second capacitor) on the base substrate.

In an exemplary implementation, as shown in FIGS. 22 to 24, an orthographic projection of the active layer T11 of the first transistor of a sub-pixel on the base substrate is at least partially overlapped with orthographic projections of the first sub-signal line Gate1A of the first scan signal line connected to the sub-pixel and the light emitting signal line connected to the sub-pixel on the base substrate.

In an exemplary implementation, an orthographic projection of the active layer T51 of the fifth transistor of a sub-pixel on the base substrate is overlapped an orthographic projection of the third sub-signal line Gate4A of the fourth scan signal line connected to the sub-pixel on the base substrate.

In an exemplary implementation, an active layer of each transistor located in the second conductive layer may include a first region, a second region, and a channel region located between the first region and the second region. In an exemplary implementation, the first region T41-1 of the active layer of the fourth transistor may simultaneously serve as the second region T51-2 of the active layer of the fifth transistor. A first region T11-1 and the second region T11-2 of the active layer T11 of the first transistor, the second region T41-2 of the active layer of the fourth transistor and the first region T51-1 of the active layer of the fifth transistor may be separately provided.

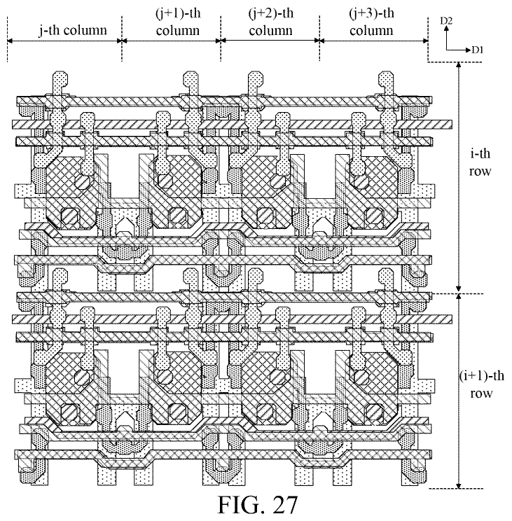

In an exemplary implementation, the active layer T11 of the first transistor is provided across the first gate electrode of the first transistor, the active layer T41 of the fourth transistor is provided across the first gate electrode of the fourth transistor, and the active layer T51 of the fifth transistor is provided across the first gate electrode of the fifth transistor.
(6) Forming a third conductive layer includes: depositing a sixth insulation thin film and a third conductive thin film sequentially on the substrate on which the aforementioned patterns are formed, patterning the sixth insulation thin film and the third conductive thin film by a patterning process to form a pattern of the sixth insulation layer and a pattern of a third conductive layer located on the sixth insulation layer, as shown in FIGS. 25 to 27, wherein FIG. 25 is a schematic diagram of a pattern of a third conductive layer of the display substrate provided in FIGS. 7 and 8, FIG. 26 is a schematic diagram of the display substrate provided in FIG. 7 after a pattern of a third conductive layer is formed and FIG. 27 is a schematic diagram of the display substrate provided in FIG. 8 after a pattern of a third conductive layer is formed. In an exemplary implementation, the third conductive layer may be referred to as a third gate metal (GATE3) layer.

In an exemplary implementation, as shown in FIGS. 25 to 27, the third conductive layer may at least include a second sub-signal line Gate1B of the first scan signal line, a fourth sub-signal line Gate4B of the fourth scan signal line, a power supply connection line VCL, a first initial signal line INIT1, a second initial signal line INIT2, and a third initial signal line INIT3, which extend at least partially along the first direction D1.

In an exemplary implementation, as shown in FIGS. 25 to 27, the second sub-signal line Gate1B of the first scan signal line may be in a line shape extending along the first direction D1. An orthographic projection of the second sub-signal line Gate1B of the first scan signal line on the base substrate is at least partially overlapped an orthographic projection of the first sub-signal line of the first scan signal line on the base substrate, and is electrically connected to the first sub-signal line of the first scan signal line. An overlapping region between a second sub-signal line Gate1B of the first scan signal line connected to a sub-pixel and the active layer of the second transistor of the sub-pixel serves as a second gate electrode T22B of the second transistor, and an overlapping region between the second sub-signal line Gate1B of the first scan signal line connected to the sub-pixel and the active layer of the fourth transistor of the sub-pixel serves as a second gate electrode T42B of the fourth transistor. The first gate electrode and the second gate electrode of the first transistor form a gate electrode of the first transistor. The first gate electrode and the second gate electrode of the fourth transistor form a gate electrode of the fourth transistor.

In an exemplary implementation, as shown in FIGS. 25 to 27, an orthographic projection of the second sub-signal line Gate1B of the first scan signal line connected to a sub-pixel on the base substrate may be located between an orthographic projection of the light emitting signal line connected to the sub-pixel on the base substrate and an orthographic projection of the first plate of the second capacitor of the sub-pixel on the base substrate.

In an exemplary implementation, as shown in FIGS. 25 to 27, the fourth sub-signal line Gate4B of the fourth scan signal line may be in a line shape extending along the first direction D1. An orthographic projection of the fourth sub-signal line Gate4B of the fourth scan signal line on the base substrate is at least partially overlapped an orthographic projection of the third sub-signal line of the fourth scan signal line on the base substrate, and is electrically connected to the third sub-signal line of the fourth scan signal line. A overlapping region between the fourth sub-signal line Gate4B of the fourth scan signal line connected to a sub-pixel and the active layer of the fifth transistor of the sub-pixel serves as a second gate electrode T52B of the fifth transistor. The first gate electrode and the second gate electrode of the fifth transistor form a gate electrode of the fifth transistor.

In an exemplary implementation, as shown in FIGS. 25 to 27, an orthographic projection of the fourth sub-signal line Gate4B of the fourth scan signal line connected to a sub-pixel on the base substrate may be located on a side of an orthographic projection of the light emitting signal line connected to the sub-pixel on the base substrate away from an orthographic projection of the first plate of the second capacitor of the sub-pixel on the base substrate.

In an exemplary implementation, as shown in FIGS. 25 to 27, the power supply connection line VCL may be a line shape in which the main body portion extends along the first direction D1. The power supply connection line VCL connected to a pixel may be located on a side of the second sub-signal line Gate1B of the first scan signal line connected to the sub-pixel away from the fourth sub-signal line Gate4B of the fourth scan signal line connected to the sub-pixel. An orthographic projection of the power supply connection line VCL on the base substrate is at least partially overlapped with an orthographic projection of the second plate of the first capacitor (also the second plate of the second capacitor) on the base substrate.

In an exemplary implementation, as shown in FIGS. 25 to 27, an orthographic projection of the power supply connection line VCL connected to a sub-pixel on the base substrate may be located between an orthographic projection of the first sub-signal line of the first scan signal line connected to the sub-pixel on the base substrate and an orthographic projection of the second scan signal line connected to the pixel on the base substrate.

In an exemplary implementation, as shown in FIGS. 25 to 27, the power supply connection line VCL may include a signal main body line 30, a first convex portion 31, a second convex portion 32, and a third convex portion 33. The signal main body line 30, the first convex portion 31, the second convex portion 32 and the third convex portion 33 may be connected to each other to form an integral structure. Herein, the first convex portion 31 may be located on a side of the signal main body line 30 close to the second sub-signal line Gate1B of the first scan signal line, the second convex portion 32 and the third convex portion 33 may be located on a side of the signal main body line 30 away from the second sub-signal line Gate1B of the first scan signal line, and the second convex portion 32 and the third convex portion 33 are arranged along the first direction D1.

In an exemplary implementation, as shown in FIGS. 25 to 27, a shape of the light main body line 30 may be a line shape extending along the first direction D1. Shapes of the first convex portion 31, the second convex portion 32 and the third convex portion 33 may be rectangular shapes.

In an exemplary implementation, as shown in FIGS. 25 to 27, orthographic projections of the second convex portion 32 and the third convex portion 33 on the base substrate are at least partially overlapped with an orthographic projection of the second plate of the first capacitor (also the second plate of the second capacitor) on the base substrate.

In an exemplary implementation, as shown in FIGS. 25 to 27, the first initial signal line INIT1 and the second initial signal line INIT2 may be the same signal line, and may be line shapes in which main body portions extend along the first direction X. The first initial signal line INIT1 (also the second initial signal line INIT2) connected to a sub-pixel is located on a side of the power supply connection line VCL connected to the sub-pixel away from the second sub-signal line Gate1B of the first scan signal line. An orthographic projection of the first initial signal line INIT1 (also the second initial signal line INIT2) on the base substrate is at least partially overlapped an orthographic projection of the second scan signal line on the base substrate.

In an exemplary implementation, as shown in FIGS. 25 to 27, the orthographic projection of the first initial signal line INIT1 (also the second initial signal line INIT2) connected to a sub-pixels on the base substrate is located between an orthographic projection of the first plate of the first capacitor of the sub-pixel on the base substrate and an orthographic projection of the third scan signal line connected to the sub-pixel on the base substrate.

In an exemplary implementation, as shown in FIGS. 25 to 27, the third initial signal line INIT3 may be a line shape in which the main body portion extends along the first direction X. The third initial signal line INIT3 is located on a side of the first initial signal line INIT1 (also the second initial signal line INIT2) away from the power supply connection line VCL. An orthographic projection of the third initial signal line INIT3 connected to a sub-pixel on the base substrate is at least partially overlapped an orthographic projection of the third scan signal line connected to the sub-pixel on the base substrate.

In an exemplary implementation, as shown in FIGS. 25 to 27, the orthographic projection of the third initial signal line INIT3 connected to a sub-pixel on the base substrate is located on a side of an orthographic projection of the second scan signal line connected to the sub-pixel on the base substrate away from an orthographic projection of the first plate the first capacitor connected to the sub-pixel on the base substrate.

In an exemplary implementation, the second sub-signal line Gate1B of the first scan signal line, the fourth sub-signal line Gate4B of the fourth scan signal line, the power supply connection line VCL, the first initial signal line INIT1, the second initial signal line INIT2 and the third initial signal line INIT3 may be in a design of equal width, or may be in a design of non-equal widths, may be straight lines, or may be bend lines, which may not only facilitate the layout of the pixel structure, but also reduce the parasitic capacitance between the signal lines, which is not limited here in the present disclosure.

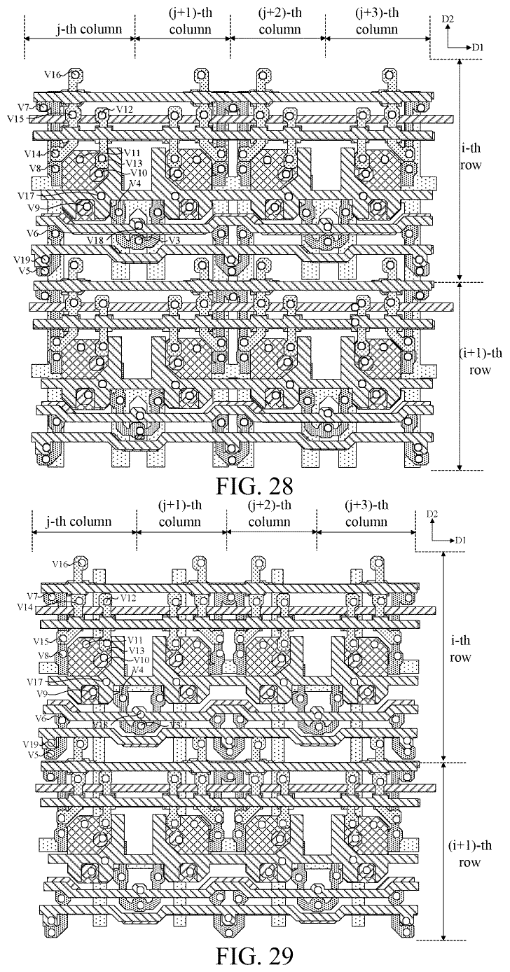

In an exemplary implementation, after the pattern of the third conductive layer is formed, a conductive treatment may be performed on the semiconductor layer by using the third conductive layer as a shield. The second semiconductor layer in a region shielded by the third conductive layer forms channel regions of the first transistor, the fourth transistor and the fifth transistor, and the second semiconductor layer in a region not shielded by the third conductive layer is made be conductive, that is, first regions and second regions of the active layers of the first transistor, the fourth transistor and the fifth transistor are all made be conductive.
(7) A pattern of a seventh insulation layer is formed. In an exemplary implementation, forming the pattern of the seventh insulation layer may include depositing a seventh insulation thin film on the base substrate on which the aforementioned patterns are formed, patterning the seventh insulation thin film using a patterning process to form a seventh insulation layer covering the third conductive layer, and the seventh insulation layer is provided with a plurality of via holes, as shown in FIGS. 28 and 29, wherein FIG. 28 is a schematic diagram of the display substrate provided in FIG. 7 after a pattern of the seventh insulation layer is formed, and FIG. 29 is a schematic diagram of the display substrate provided in FIG. 8 after a pattern of the seventh insulation layer is formed.

In an exemplary implementation, as shown in FIGS. 28 and 29, the plurality of via holes of the seventh insulation layer may at least include a third via hole V3 to a nineteenth via hole V19 located in at least one sub-pixel.

In an exemplary implementation, the third via hole of a sub-pixel is the same as the third via hole of one of adjacent sub-pixels located in the same row, the fifth via hole of a sub-pixel is the same as the fifth via hole of another adjacent sub-pixel located in the same row, and the seventh via hole of a sub-pixel is the same as the seventh via hole of another adjacent sub-pixel located in the same row.

In an exemplary implementation, as shown in FIGS. 28 and 29, an orthographic projection of the third via hole V3 on the base substrate is located within a range of an orthographic projection of the first region of the active layer of the second transistor on the base substrate. The third insulation layer, the fourth insulation layer, the fifth insulation layer and the sixth insulation layer within the third via hole V3 are etched away to expose a surface of the first region of the active layer of the second transistor, and the third via hole V3 is configured such that the first electrode of the second transistor (also the initial connection line ICL) formed subsequently is connected to the first region of the active layer of the second transistor through the third via hole V3.

In an exemplary implementation, as shown in FIGS. 28 and 29, an orthographic projection of the fourth via hole V4 on the base substrate is located within a range of an orthographic projection of the second region of the active layer of the second transistor (also the second region of the active layer of the sixth transistor) on the base substrate. The third insulation layer, the fourth insulation layer, the fifth insulation layer and the sixth insulation layer within the fourth via hole V4 are etched away to expose a surface of the second region of the active layer of the second transistor (also the second region of the active layer of the sixth transistor), and the fourth via hole V4 is configured such that the second electrode of the second transistor (also the second electrode of the sixth transistor) formed subsequently is connected to the second region of the active layer of the second transistor (also the second region of the active layer of the sixth transistor) through the via hole V4.

In an exemplary implementation, as shown in FIGS. 28 and 29, an orthographic projection of the fifth via hole V5 on the base substrate is located within a range of an orthographic projection of the first region of the active layer of the third transistor on the base substrate. The third insulation layer, the fourth insulation layer, the fifth insulation layer and the sixth insulation layer within the fifth via hole V5 are etched away to expose a surface of the first region of the active layer of the third transistor, and the fifth via hole V5 is configured such that the first electrode of the third transistor formed subsequently is connected to the first region of the active layer of the third transistor through the fifth via hole V5.

In an exemplary implementation, as shown in FIGS. 28 and 29, an orthographic projection of the sixth via hole V6 on the base substrate is located within a range of an orthographic projection of the second region of the active layer of the third transistor on the base substrate, The third insulation layer, the fourth insulation layer, the fifth insulation layer and the sixth insulation layer within the sixth via hole V6 are etched away to expose a surface of the second region of the active layer of the third transistor, and the sixth via hole V6 is configured such that the second electrode of the third transistor (also the second electrode of the fourth transistor T4, the first electrode of the sixth transistor, and the second electrode of the seventh transistor) formed subsequently is connected to the second region of the active layer of the third transistor through the sixth via hole V6.

In an exemplary implementation, as shown in FIGS. 28 and 29, an orthographic projection of the seventh via hole V7 on the base substrate is located within a range of an orthographic projection of the first region of the active layer of the seventh transistor on the base substrate. The third insulation layer, the fourth insulation layer, the fifth insulation layer and the sixth insulation layer within the seventh via hole V7 are etched away to expose a surface of the first region of the active layer of the seventh transistor, and the seventh via hole V7 is configured such that the first electrode of the seventh transistor formed subsequently is connected to the first region of the active layer of the seventh transistor through the seventh via hole V7.

In an exemplary implementation, as shown in FIGS. 28 and 29, an orthographic projection of the eighth via hole V8 on the base substrate is located within a range of an orthographic projection of the second region of the active layer of the seventh transistor (also the first region of the sixth transistor) on the base substrate. The third insulation layer, the fourth insulation layer, the fifth insulation layer and the sixth insulation layer within the eighth via hole V8 are etched away to expose a surface of the second region of the active layer of the seventh transistor (also the first region of the sixth transistor), and the eighth via hole V8 is configured such that the second electrode of the third transistor (also the second electrode of the fourth transistor, the first electrode of the sixth transistor and the second electrode of the seventh transistor) formed subsequently is connected to the second region of the active layer of the seventh transistor (also the first region of the sixth transistor) through the eighth via hole V8.

In an exemplary implementation, as shown in FIGS. 28 and 29, an orthographic projection of the ninth via hole V9 on the base substrate is located within a range of an orthographic projection of the first via hole on the base substrate. The fifth insulation layer and the sixth insulation layer within the ninth via hole V9 are etched away to expose a surface of the first plate of the first capacitor, and the ninth via hole V9 is configured such that the first connection electrode formed subsequently is connected to the first plate of the first capacitor through the ninth via hole V9.

In an exemplary implementation, as shown in FIGS. 28 and 29, an orthographic projection of the tenth via hole V10 on the base substrate is located within a range of an orthographic projection of the second via hole on the base substrate. The fifth insulation layer and the sixth insulation layer within the tenth via hole V10 are etched away to expose a surface of the first plate of the second capacitor (also the gate electrode of the sixth transistor), and the tenth via hole V10 is configured such that the second electrode of the first transistor formed subsequently is connected to the first plate of the second capacitor (also the gate electrode of the sixth transistor) through the tenth via hole V10.

In an exemplary implementation, as shown in FIGS. 28 and 29, an orthographic projection of the eleventh via hole V11 on the base substrate is located within a range of an orthographic projection of the second plate of the first capacitor on the base substrate. The fifth insulation layer and the sixth insulation layer within the eleventh via hole V11 are etched away, the eleventh via hole V11 exposes a surface of the second plate of the first capacitor (also the second plate of the second capacitor), and the eleventh via hole V11 is configured such that the first electrode of the fourth transistor (also the second electrode of the fifth transistor) formed subsequently is connected to the second plate of the first capacitor (also the second plate of the second capacitor) through the eleventh via hole V11.

In an exemplary implementation, as shown in FIGS. 28 and 29, an orthographic projection of the twelfth via hole V12 on the base substrate is located within a range of an orthographic projection of the first region of the active layer of the first transistor on the base substrate. The sixth insulation layer within the twelfth via hole V12 are etched away to expose a surface of the first region of the active layer of the first transistor, and the twelfth via hole V12 is configured such that the first electrode of the first transistor formed subsequently is connected to the first region of the active layer of the first transistor through the twelfth via hole V12.

In an exemplary implementation, as shown in FIGS. 28 and 29, an orthographic projection of the thirteenth via hole V13 on the base substrate is located within a range of an orthographic projection of the second region of the active layer of the first transistor on the base substrate. The sixth insulation layer within the thirteenth via hole V13 are etched away to expose a surface of the second region of the active layer of the first transistor, and the thirteenth via hole V13 is configured such that the second electrode of the first transistor formed subsequently is connected to the second region of the active layer of the first transistor through the thirteenth via hole V13.

In an exemplary implementation, as shown in FIGS. 28 and 29, an orthographic projection of the fourteenth via hole V14 on the base substrate is located within a range of an orthographic projection of the first region of the active layer of the fourth transistor (also the second region of the active layer of the fifth transistor) on the base substrate. The sixth insulation layer within the fourteenth via hole V14 is etched away to expose a surface of the first region of the active layer of the fourth transistor (also the second region of the active layer of the fifth transistor), and the fourteenth via hole V14 is configured such that the first electrode of the fourth transistor (also the second electrode of the fifth transistor) formed subsequently is connected to the first region of the active layer of the fourth transistor (also the second region of the active layer of the fifth transistor) through the fourteenth via hole V14.

In an exemplary implementation, as shown in FIGS. 28 and 29, an orthographic projection of the fifteenth via hole V15 on the base substrate is located within a range of an orthographic projection of the second region of the active layer of the fourth transistor on the base substrate. The sixth insulation layer within the fifteenth via hole V15 is etched away to expose a surface of the second region of the active layer of the fourth transistor, and the fifteenth via hole V15 is configured such that the second electrode of the third transistor (also the second electrode of the fourth transistor, the first electrode of the sixth transistor and the second electrode of the seventh transistor) formed subsequently is connected to the second region of the active layer of the fourth transistor through the fifteenth via hole V15.

In an exemplary embodiment, as shown in FIGS. 28 and 29, an orthographic projection of the sixteenth via hole V16 on the base substrate is located within a range of an orthographic projection of the first region of the active layer of the fifth transistor on the base substrate. The sixth insulation layer within the sixteenth via hole V16 is etched away, the fifteenth via hole V15 exposes a surface of the first region of the active layer of the fifth transistor, and the sixteenth via hole V16 is configured such that the first electrode of the fifth transistor formed subsequently is connected to the first region of the active layer of the fifth transistor through the sixteenth via hole V16.

In the exemplary implementation, as shown in FIGS. 28 and 29, an orthographic projection of the seventeenth via hole V17 on the base substrate is located within a range of an orthographic projection of the power supply connection line on the base substrate to expose a surface of the power supply connection line, and the seventeenth via hole V17 is configured such that the first connection electrode formed subsequently is connected to the power supply connection line through the seventeenth via hole V17.

In an exemplary implementation, as shown in FIGS. 28 and 29, an orthographic projection of the eighteenth via hole V18 on the base substrate is located within a range of an orthographic projection of the first initial signal line (also the second initial signal line) on the base substrate to expose a surface of the first initial signal line (also the second initial signal line), and the eighteenth via hole V18 is configured such that the first electrode of the second transistor (also the initial connection line ICL) formed subsequently is connected to the first initial signal line (also the second initial signal line) through the eighteenth via hole V18.

In an exemplary implementation, as shown in FIGS. 28 and 29, an orthographic projection of the nineteenth via hole V19 on the base substrate is located within a range of an orthographic projection of the third initial signal line on the base substrate, the nineteenth via hole exposes a surface of the third initial signal line, and the nineteenth via hole V19 is configured such that the first electrode of the third transistor subsequently formed is connected to the third initial signal line through the nineteenth via hole V19.

In an exemplary implementation, a virtual straight line extending along the second direction D2 may pass through the third via hole V3 and the eighteenth via hole V18.

In an exemplary implementation, a virtual straight line extending along the second direction D2 may pass through the fifth via hole V5 and the nineteenth via hole V19.

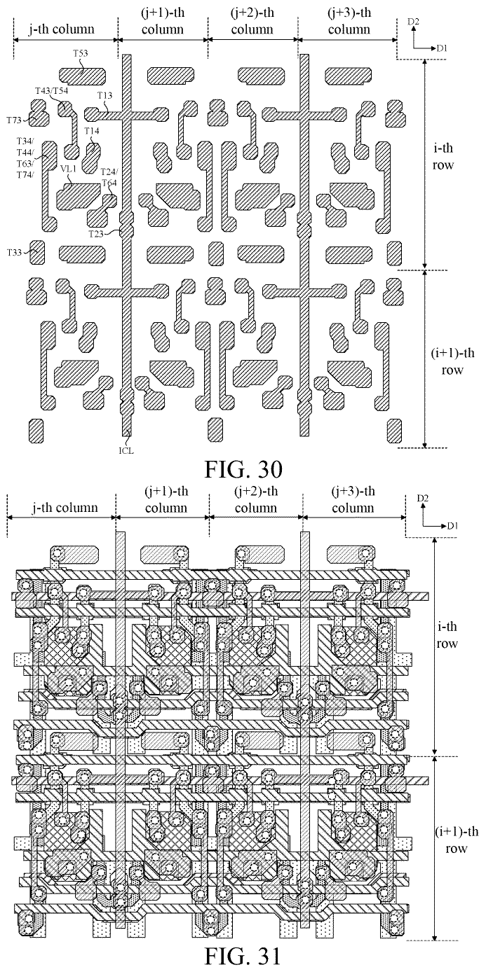

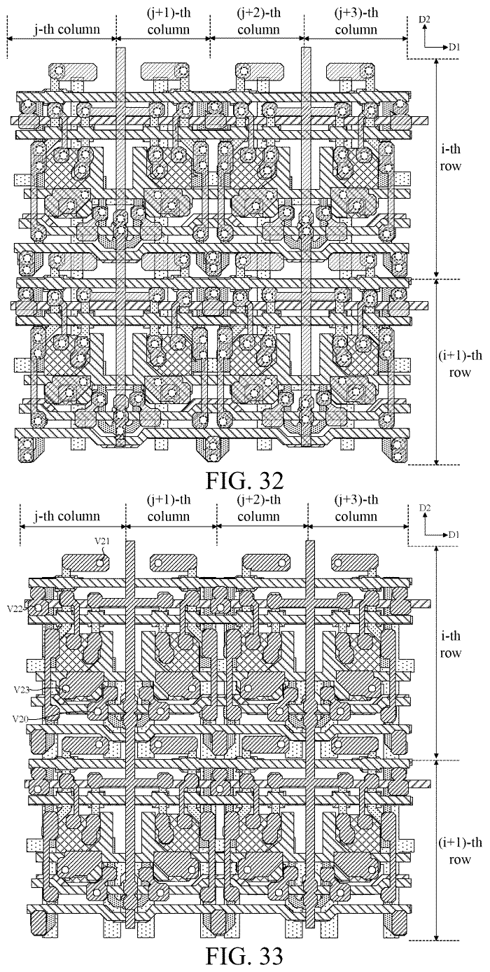

In an exemplary implementation, a virtual straight line extending in the second direction may pass through the eighth via hole V8 and the eighth via hole V15.
(9) A pattern of a fourth conductive layer is formed. (8) In an exemplary implementation, forming the pattern of the fourth conductive layer may include depositing a fourth conductive thin film on the base substrate on which the aforementioned patterns are formed, and patterning the fourth conductive thin film using a patterning process to form the pattern of the fourth conductive layer arranged on the seventh insulation layer, as shown in FIGS. 30 to 32, wherein FIG. 30 is a schematic diagram of a pattern of a fourth conductive layer of the display substrate provided in FIG. 7 and FIG. 8, FIG. 31 is a schematic diagram of the display substrate provided in FIG. 7 after a pattern of a fourth conductive layer is formed, and FIG. 32 is a schematic diagram of the display substrate provided in FIG. 8 after a pattern of a fourth conductive layer is formed. In an exemplary implementation, the fourth conductive layer may be referred to as a first source drain metal (SD1) layer.

In an exemplary implementation, as shown in FIGS. 30 to 32, the pattern of the fourth conductive layer may at least include an initial connection line ICL extending at least partially along the second direction D2, and a first electrode T13 and a second electrode T14 of the first transistor, a first electrode T23 and a second electrode T24 of the second transistor, a first electrode T33 and a second electrode T34 of the third transistor, a first electrode T43 and a second electrode T44 of the fourth transistor, a first electrode T53 and a second electrode T54 of the fifth transistor, a first electrode T63 and a second electrode T64 of the sixth transistor, a first electrode T73 and a second electrode T74 of the seventh transistor, and a first connection electrode VL1, which are located in at least one sub-pixel.

In an exemplary implementation, as shown in FIGS. 30 to 32, any of a first electrode T13 and a second electrode T14 of the first transistor, a first electrode T23 and a second electrode T24 of the second transistor, a first electrode T33 and a second electrode T34 of the third transistor, a first electrode T43 and a second electrode T44 of the fourth transistor, a first electrode T53 and a second electrode T54 of the fifth transistor, a first electrode T63 and a second electrode T64 of the sixth transistor, a first electrode T73 and a second electrode T74 of the seventh transistor, and a first connection electrode VL1, which are located in an adjacent sub-pixel in the same row, is arranged symmetrically with respect to a virtual straight line extending along the second direction D2.

In an exemplary implementation, as shown in FIGS. 30 to 32, the initial connection line ICL is located between two adjacent columns of sub-pixels in which the active layers of the second transistor are connected to each other, and is electrically connected to the adjacent two columns of sub-pixels, respectively. The initial connection line ICL coincides with the symmetry axes of two adjacent columns of sub-pixels.

In an exemplary implementation, as shown in FIGS. 30 to 32, a shape of the initial connection line ICL may be a line shape extending along the second direction D2. An overlapping region between the initial connection line ICL and the first region of the active layer of the second transistor may simultaneously serve as the first electrode T23 of the second transistor. The initial connection line ICL (also the first electrode T23 of the second transistor) is connected to the first region of the active layer of the second transistor through the third via hole, and is connected to the first initial signal line (also the second initial signal line) through the eighteenth via hole.

In an exemplary implementation, as shown in FIGS. 30 to 32, in the first direction D1, a first electrode T13 and a second electrode T14 of the first transistor, a first electrode T23 and a second electrode T24 of the second transistor, a first electrode T33 and a second electrode T34 of the third transistor, a first electrode T43 and a second electrode T44 of the fourth transistor, a first electrode T53 and a second electrode T54 of the fifth transistor, a first electrode T63 and a second electrode T64 of the sixth transistor, a first electrode T73 and a second electrode T74 of the seventh transistor, and a first connection electrode VL1, which are located in at least one sub-pixel, may be located on the same side of the initial connection line ICL.

In the exemplary implementation, as shown in FIGS. 30 to 32, the first electrode T13 of the first transistor and the initial connection line ICL are connected to each other to form an integral structure. A shape of the first electrode T13 of the first transistor may be a line shape extending along the first direction D1. The first electrode T13 of the first transistor is connected to the first region of the active layer of the first transistor through the twelfth via hole V12.

In an exemplary implementation, as shown in FIGS. 30 to 32, the second electrode T14 of the first transistor is provided separately. A shape of the second electrode T14 of the first transistor may be a block shape. The second electrode T14 of the first transistor is connected to the second region of the active layer of the first transistor through the thirteenth via hole, and is connected to the first plate of the second capacitor (also the gate electrode of the sixth transistor) through the tenth via hole.

In an exemplary implementation, as shown in FIGS. 30 to 32, the second electrode T24 of the second transistor and the second electrode T64 of the sixth transistor may be of a block structure connected to each other. A shape of the second electrode T24 of the second transistor (also the second electrode T64 of the sixth transistor) may be a dumbbell shape. The second electrode T24 of the second transistor (the second electrode T64 of the sixth transistor) may be connected to the second region of the active layer of the second transistor (also the second region of the active layer of the sixth transistor) through the fourth via hole.

In an exemplary implementation, as shown in FIGS. 30 to 32, the first electrode T33 of the third transistor is separately provided. A shape of the first electrode T33 of the third transistor may be a block shape. The first electrode T33 of the third transistor is connected to the first region of the active layer of the third transistor through the fifth via hole, and is connected to the third initial signal line through the nineteenth via hole.

In an exemplary implementation, as shown in FIGS. 30 to 32, the second electrode T34 of the third transistor, the second electrode T44 of the fourth transistor, the first electrode T63 of the sixth transistor, and the second electrode T74 of the seventh transistor may be connected to each other to form an integral structure. A shape of the second electrode T34 of the third transistor (also the second electrode T44 of the fourth transistor, the first electrode T63 of the sixth transistor, and the second electrode T74 of the seventh transistor) may be a dumbbell shape extending along the second direction D2. The second electrode T34 of the third transistor (also the second electrode T44 of the fourth transistor, the first electrode T63 of the sixth transistor and the second electrode T74 of the seventh transistor) is connected to the second region of the active layer of the third transistor through the sixth via hole, is connected to the second region of the active layer of the seventh transistor (also the first region of the sixth transistor) through the eighth via hole, and is connected to the second region of the active layer of the fourth transistor through the fifteenth via hole.

In an exemplary implementation, as shown in FIGS. 30 to 32, the first electrode T43 of the fourth transistor and the second electrode T54 of the fifth transistor may be of an integral structures connected to each other. A shape of the first electrode T43 of the fourth transistor (also the second electrode T54 of the fifth transistor) may be a dumbbell shape in which the main body portion extends along the second direction D2. The first electrode T43 of the fourth transistor (also the second electrode T54 of the fifth transistor) is connected to the second plate of the first capacitor (also the second plate of the second capacitor) through the eleventh via hole, and is connected to the first region of the active layer of the fourth transistor (also the second region of the active layer of the fifth transistor) through the fourteenth via hole.

In the exemplary implementation, as shown in FIGS. 30 to 32, the first electrode T53 of the fifth transistor is provided separately. A shape of the first electrode T53 of the fifth transistor may be a strip shape extending along the first direction D1. The first electrode T53 of the fifth transistor is connected to the first region of the active layer of the fifth transistor through the sixteenth via hole.

In the exemplary implementation, as shown in FIGS. 30 to 32, the first electrode T73 of the seventh transistor is provided separately. A shape of the first electrode T73 of the seventh transistor may be a gourd shape. The first electrode T73 of the seventh transistor is connected to the first region of the active layer of the seventh transistor through the seventh via hole.

In an exemplary implementation, as shown in FIGS. 30 to 32, a shape of the first connection electrode VL1 may be a rectangular shape. The first connection electrode VL1 is connected to the power supply connection line through the seventeenth via hole, and is connected to the first plate of the first capacitor through the ninth via hole.

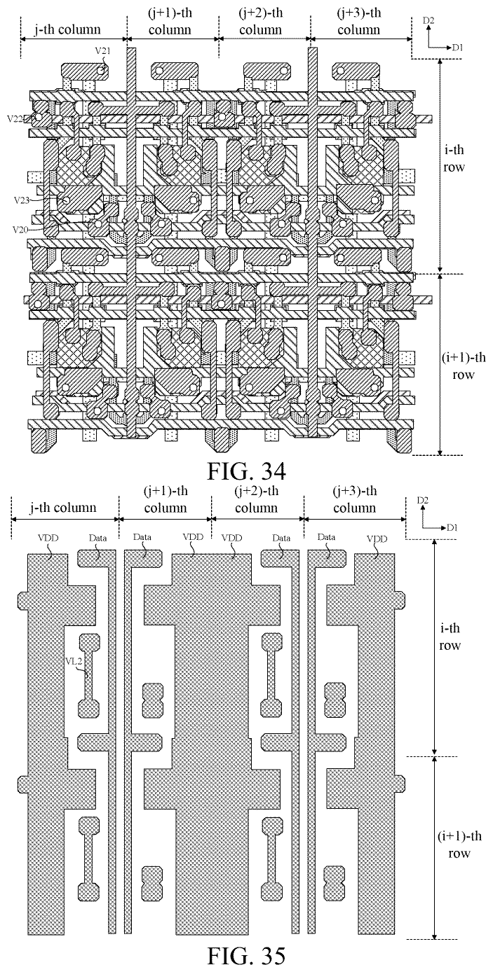

In an exemplary implementation, as shown in FIGS. 30 to 32, an orthographic projection of the first connection electrode on the base substrate is at least partially overlapped with orthographic projections of the second convex portion and the third convex portion of the power supply connection line on the base substrate.
(10) A pattern of a first planarization layer is formed. In an exemplary implementation, forming the pattern of the first planarization layer may include depositing an eighth insulation thin film on the base substrate on which the aforementioned patterns are formed, patterning the eighth insulation thin film using a patterning process to form an eighth insulation layer covering the fourth conductive layer, coating a first planarization thin film on the eighth insulation layer, patterning the first planarization thin film through the patterning process to form a pattern of the first planarization layer covering the aforementioned patterns, and the first planarization layer is provided with a plurality of patterns of via holes, as shown in FIGS. 33 and 34, wherein FIG. 33 is a schematic diagram of the display substrate provided in FIG. 7 after a pattern of an eighth insulation layer is formed, and FIG. 34 is a schematic diagram of the display substrate provided in FIG. 8 after a pattern of an eighth insulation layer is formed.

In an exemplary implementation, as shown in FIGS. 33 and 34, the plurality of via holes of the first planarization layer may at least include a twentieth via hole V20 to a twenty-third via hole V23.

In an exemplary embodiment, as shown in FIGS. 33 and 34, an orthographic projection of the twentieth via hole V20 on the base substrate is located within a range of an orthographic projection of the second electrode of the second transistor (also the second electrode of the sixth transistor) on the base substrate. The eighth insulation layer within the twentieth via hole V20 is etched away to expose a surface of the second electrode of the second transistor (also the second electrode of the sixth transistor), and the twentieth via hole V20 is configured such that the second connection electrode formed subsequently is connected to the second electrode of the second transistor (also the second electrode of the sixth transistor) through the twentieth via hole V20.

In an exemplary implementation, as shown in FIGS. 33 and 34, an orthographic projection of the twenty-first via hole V21 on the base substrate is within a range of an orthographic projection of the first electrode of the fifth transistor on the base substrate. The eighth insulation layer within the twenty-first via hole V21 is etched away to expose a surface of the first electrode of the first transistor, and the twenty-first via hole V21 is configured such that the data signal line formed subsequently is connected to the first electrode of the fifth transistor through the twenty-first via hole V12.

In an exemplary implementation, as shown in FIGS. 33 and 34, an orthographic projection of the twenty-second via hole V22 on the base substrate is within a range of an orthographic projection of the first electrode of the seventh transistor on the base substrate. The eighth insulation layer within the twenty-second via hole V22 is etched away to expose a surface of the first electrode of the seventh transistor, and the twenty-second via hole V22 is configured such that the first power supply line formed subsequently is connected to the first electrode of the seventh transistor through the twenty-second via hole V22.

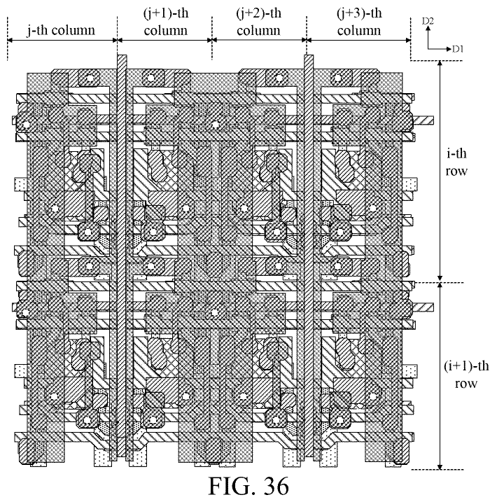

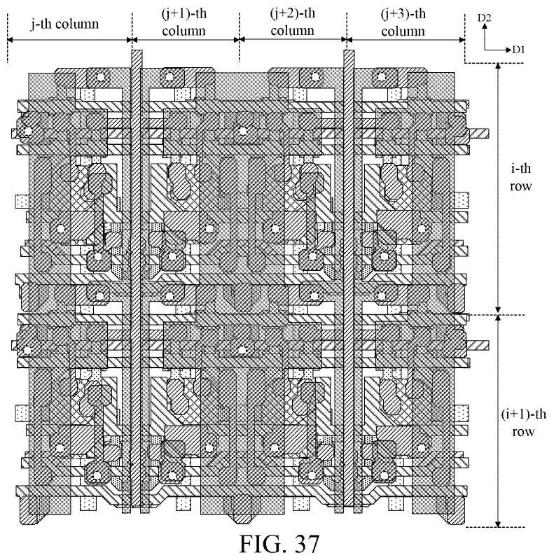

In an exemplary implementation, as shown in FIGS. 33 and 34, an orthographic projection of the twenty-third via hole 23 on the base substrate is located within a range of an orthographic projection of the first connection electrode. The eighth insulation layer within the twenty-third via hole V23 is etched away to expose a surface of the first connection electrode, and the twenty-third via hole V23 is configured such that the first power supply line formed subsequently is connected to the first connection electrode through the twenty-third via hole V23.
(11) Forming the pattern of the fifth conductive layer includes: depositing a fifth conductive thin film on the substrate on which the aforementioned patterns are formed, patterning the fifth conductive thin film through a patterning process to form the pattern of the fifth conductive layer, as shown in FIGS. 35 to 37, wherein FIG. 35 is a schematic diagram of a pattern of a fifth conductive layer of the display substrate provided in FIGS. 7 and 8, FIG. 36 is a schematic diagram of the display substrate provided in FIG. 7 after a pattern of a fifth conductive layer is formed, and FIG. 37 is a schematic diagram of the display substrate provided in FIG. 8 after a pattern of a fifth conductive layer is formed. In an exemplary implementation, the fifth conductive layer may be referred to as a second source-drain metal (SD2) layer.

In an exemplary implementation, as shown in FIGS. 35 to 37, the fifth conductive layer may at least include a second connection electrode VL2 located in at least one sub-pixel and a data signal line Data and a first power supply line VDD extending at least partially along the second direction D2. A plurality of data signal lines Data are arranged along the first direction D1, and a plurality of first power supply lines VDD are arranged along the first direction D1.

In an exemplary implementation, as shown in FIGS. 35 to 37, data signal lines Data connected to adjacent sub-pixels are axially symmetric with respect to a virtual straight line extending along the second direction D2. First power supply lines VDD connected to adjacent sub-pixels are axially symmetric with respect to a virtual straight line extending along the second direction D2.

In the exemplary implementation, as shown in FIGS. 35 to 37, the data signal line Data and the first power supply line VDD connected to a sub-pixel are located on different sides of the second connection electrode of the sub-pixel.

In an exemplary implementation, as shown in FIGS. 35 to 37, the first power supply line VDD is connected to one adjacent power supply line, and is arranged at intervals from another adjacent power supply line. Two data signal lines Data are provided between the two first power supply lines arranged at intervals.

In an exemplary implementation, as shown in FIGS. 35 to 37, an orthographic projection of the initial connection line ICL on the base substrate is located between orthographic projections of the data signal lines connected to two adjacent columns of sub-pixels connected to the initial connection line ICL on the base substrate, and an orthographic projection of the first power supply line connected to a sub-pixel on the base substrate is located on a side of the data signal line connected to the sub-pixel away from the initial connection line ICL connected to the sub-pixel.

In an exemplary implementation, as shown in FIGS. 35 to 37, a shape of the data signal line Data may be a line shape in which the main body portion extends along the second direction D2. The data signal line Data connected to a sub-pixel is connected to the first electrode of the fifth transistor of the sub-pixel through the twenty-first via hole.

In an exemplary implementation, as shown in FIGS. 35 to 37, a shape of the first power supply line VDD may be a line shape in which the main body portion extends along the second direction D2. The first power supply line VDD connected to a sub-pixel is connected to the first electrode of the seventh transistor through the twenty-second via hole, and is connected to the first connection electrode through the twenty-third via hole.

In an exemplary implementation, as shown in FIGS. 35 to 37, an orthographic projection of the first power supply line VDD on the base substrate is at least partially overlapped with orthographic projections of the second plate of the first capacitor (also the second plate of the second capacitor) and the signal main body portion and the second convex portion of the power supply connection line on the base substrate.

In an exemplary implementation, as shown in FIGS. 35 to 37, a shape of the second connection electrode VL2 may be a line shape or a gourd shape at least partially along the second direction D2. The second connection electrode VL2 is connected to the second electrode of the second transistor (also the second electrode of the sixth transistor) through the twenty-third via hole, and is configured to be connected to an anode of the light emitting device formed subsequently. Shapes of the connection electrodes connected to anodes of different light emitting devices may be different.

In an exemplary implementation, a width of the first power supply line VDD may be greater than a width of the data signal line Data.
(12) Forming the pattern of the second planarization layer includes: coating a second planarization thin film on the substrate on which the aforementioned patterns are formed, and patterning the second planarization thin film through a patterning process to form the pattern of the second planarization layer covering the aforementioned patterns.

So far, a drive circuit layer has been manufactured on the base substrate. In a plane parallel to the display substrate, the drive circuit layer may include a plurality of pixel drive circuits, and a pixel drive circuit is connected to a first scan signal line, a second scan signal line, a third scan signal line, a fourth scan signal line, a light emitting signal line, a first initial signal line, a second initial signal line, a third initial signal line, a data signal line, and a first power supply line. The drive circuit layer may be arranged on the base substrate. The drive circuit layer may include a first insulation layer, a light shielding layer, a second insulation layer, a first semiconductor layer, a third insulation layer, a first conductive layer, a fourth insulation layer, a second conductive layer, a fifth insulation layer, a second semiconductor layer, a sixth insulation layer, a third conductive layer, a seventh insulation layer, a fourth conductive layer, an eighth insulation layer, a first planarization layer, a fifth conductive layer and a second planarization layer which are arranged sequentially on the base substrate.

In an exemplary implementation, the first semiconductor layer may be an amorphous silicon layer or a polysilicon layer.

In an exemplary embodiment, the second semiconductor layer may be a metal oxide layer. Herein, the metal oxide layer may use an oxide including indium and tin, an oxide including tungsten and indium, an oxide including tungsten, indium and zinc, an oxide including titanium and indium, an oxide including titanium, indium and tin, an oxide including indium and zinc, an oxide including silicon, indium and tin, or an oxide including indium or gallium and zinc. The metal oxide layer may be a single layer, a double-layer, or a multi-layer.

In an exemplary implementation, the first conductive layer, the second conductive layer, the third conductive layer, the fourth conductive layer, and the fifth conductive layer may be made of a metal material, such as any one or more of Argentum (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation, the first insulation layer, the second insulation layer, the third insulation layer, the fourth insulation layer, the fifth insulation layer, the sixth insulation layer, the seventh insulation layer and the eighth insulation layer may be made of any one or more of silicon oxide (SiOx), silicon nitride (SiNx) and silicon oxynitride (SiON), and may be a single layer, a plurality of layers, or a composite layer.

In an exemplary implementation, the first planarization layer and the second planarization layer may be made of an organic material, such as resin or the like.

In an exemplary implementation, after manufacturing of the drive circuit layer is completed, a light emitting structure layer is manufactured on the drive circuit layer, and a manufacturing process of the light emitting structure layer may include following operations.

An anode conductive thin film is deposited on the base substrate on which the aforementioned patterns are formed, the anode conductive thin film is patterned through a patterning process to form a pattern of the anode conductive thin film arranged on the second planarization layer, a pixel definition thin film is deposited on the base substrate on which the aforementioned patterns are formed, the pixel definition thin film is pattern through a patterning process to form a pattern of a pixel definition layer exposing the pattern of the anode conductive layer, an organic light emitting material is coated on the base substrate on which the pattern of the pixel definition layer is formed, the organic light emitting material is patterned through a patterning process to form a pattern of an organic structure layer, a cathode conductive thin film is deposited on the base substrate on which the pattern of the organic material layer is formed, and the cathode conductive thin film is patterned through a patterning process to form the cathode conductive layer.

So far, the light emitting structure layer has been manufactured on the base substrate.

In an exemplary implementation, a subsequent manufacturing process may include forming an encapsulation structure layer on the cathode conductive layer, wherein the encapsulation structure layer may include a first encapsulation layer, a second encapsulation layer and a third encapsulation layer which are stacked. The first encapsulation layer and the third encapsulation layer may be made of an inorganic material, the second encapsulation layer may be made of an organic material, and the second encapsulation layer is arranged between the first encapsulation layer and the third encapsulation layer to ensure that external water vapor cannot enter the light emitting structure layer.

In an exemplary implementation, the anode conductive layer includes at least a plurality of anode patterns. The plurality of anode patterns may include an anode of a first light emitting device, an anode of a second light emitting device, an anode of a third light emitting device, and an anode of a fourth light emitting device, wherein the anode of the first light emitting device is located at a red sub-pixel emitting red light, the anode of the second light emitting device may be located at a blue sub-pixel emitting blue light, the anode of the third light emitting device may be located at a first green sub-pixel emitting green light, and the anode of the fourth light emitting device may be located at a second green sub-pixel emitting green light.

In an exemplary implementation, the anode of the first light emitting device and the anode of the second light emitting device may be alternately arranged along the first direction D1, and the anode of the third light emitting device and the anode of the fourth light emitting device may be alternately arranged along the first direction D1 Alternatively, the anode of the first light emitting device and the anode of the second light emitting device may be alternately arranged along the second direction D2, and the anode of the third light emitting device and the anode of the fourth light emitting device may be alternately arranged along the second direction D2.

In an exemplary implementation, four sub-pixels in one pixel unit may have the same or different anode shapes and areas.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary implementation, the organic structure layer may include at least an organic light emitting layer of the light emitting device.

In an exemplary implementation, the cathode conductive layer may at least include cathodes of a plurality of light emitting devices.

In an exemplary implementation, the cathode layer may be made of a metal material, such as any one or more of argentum (Ag), copper (Cu), aluminum (Al), and molybdenum (Mo), or a conductive alloy material of the above metals, such as an Aluminum Neodymium alloy (AlNd) or a Molybdenum Niobium alloy (MoNb), and may have a single-layer structure or a multi-layer composite structure, such as Mo/Cu/Mo. For example, the fourth conductive layer may be of a three-layer stacked structure formed of titanium, aluminum, and titanium.

The display substrate according to the embodiment of the present disclosure may be applied to a display product with any resolution.

An embodiment of the present disclosure also provides a drive method of a pixel drive circuit, configured to drive a pixel drive circuit. The method for driving the pixel drive circuit according to the embodiment of the present disclosure may include following steps.

In step 100, a node control sub-circuit drives a signal of a first node, provides a signal of the second initial signal line to a second node, and provides a signal of the third initial signal line to a third node through signals of a first initial signal line, a data signal line and a first power supply line under the control of signals of a first scan signal line, a second scan signal line, a third scan signal line and a fourth scan signal line.

In step 200, the light emitting control sub-circuit provides the signal of the first power supply line to the third node under the control of the signal of the light emitting signal line, and the drive sub-circuit outputs a drive current to the second node under the control of the signals of the first node and the third node.

An embodiment of the present disclosure further provides a display apparatus including a display substrate.

The display substrate is the display substrate according to any of the aforementioned embodiments, and has similar implementation principles and implementation effects, which will not be repeated here.

In an exemplary implementation, the display apparatus may be any product or component with a display function, such as a liquid crystal panel, electronic paper, an OLED panel, an Active-Matrix Organic Light Emitting Diode (AMOLED) panel, a mobile phone, a tablet computer, a television, a display, a notebook computer, a digital photo frame, or a navigator.

The accompanying drawings of the present disclosure only involve the structures involved in the embodiments of the present disclosure, and other structures may refer to usual designs.

For the sake of clarity, a thickness and size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although the implementations of the present disclosure are disclosed above, the contents are only implementations used for ease of understanding of the present disclosure, but not intended to limit the present disclosure. Any of those skilled in the art of the present disclosure can make any modifications and variations in the implementation and details without departing from the spirit and scope of the present disclosure. However, the protection scope of the present disclosure should be subject to the scope defined by the appended claims.

1. A pixel drive circuit configured to drive a light emitting device, wherein the pixel drive circuit comprises: a node control sub-circuit, a light emitting control sub-circuit, and a drive sub-circuit;
the node control sub-circuit is electrically connected to a first node, a second node, a third node, a first scan signal line, a second scan signal line, a third scan signal line, a fourth scan signal line, a first initial signal line, a second initial signal line, a third initial signal line, a data signal line and a first power supply line respectively, and the node control sub-circuit is configured to drive a signal of the first node, provide a signal of the second initial signal line to the second node, and provide a signal of the third initial signal line to the third node through signals of the first initial signal line, the data signal line and the first power supply line under control of signals of the first scan signal line, the second scan signal line, the third scan signal line and the fourth scan signal line;
the light emitting control sub-circuit is electrically connected to the first power supply line, a light emitting signal line and the third node respectively, and is configured to provide a signal of the first power supply line to the third node under control of a signal of the light emitting signal line;
the drive sub-circuit is electrically connected to the first node, the second node, and the third node respectively, and is configured to output a drive current to the second node under control of signals of the first node and the third node;
the light emitting device is electrically connected to the second node and a second power supply line respectively;
the node control sub-circuit comprises: an energy storage sub-circuit which comprises: a first capacitor and a second capacitor, wherein the first capacitor and the second capacitor each comprise a first plate and a second plate;
the first plate of the first capacitor is electrically connected to the first power supply line, and the second plate of the first capacitor is electrically connected to a fourth node; and
the first plate of the second capacitor is electrically connected to the first node, and the second plate of the second capacitor is electrically connected to the fourth node.

2. The pixel drive circuit according to claim 1, wherein the node control sub-circuit further comprises: a reset sub-circuit, a compensation sub-circuit, and a write sub-circuit;
the reset sub-circuit is electrically connected to the first node, the second node, the third node, the first scan signal line, the second scan signal line, the third scan signal line, the first initial signal line, the second initial signal line and the third initial signal line respectively, and the reset sub-circuit is configured to provide a signal of the first initial signal line to the first node under control of a signal of the first scan signal line, provide the signal of the second initial signal line to the second node under control of a signal of the second scan signal line, and provide the signal of the third initial signal line to the third node under control of a signal of the third scan signal line;
the compensation sub-circuit is electrically connected to the third node, the fourth node and the first scan signal line respectively, and is configured to provide a signal of the third node to the fourth node under control of the signal of the first scan signal line to compensate a signal of the fourth node; and
the write sub-circuit is electrically connected to the fourth node, the fourth scan signal line, and the data signal line respectively, and is configured to provide a signal of the data signal line to the fourth node under control of a signal of the fourth scan signal line.

3. The pixel drive circuit according to claim 2, wherein the reset sub-circuit comprises a first transistor, a second transistor and a third transistor;
a gate electrode of the first transistor is connected to the first scan signal line, a first electrode of the first transistor is connected to the first initial signal line, and a second electrode of the first transistor is connected to the first node;
a gate electrode of the second transistor is connected to the second scan signal line, a first electrode of the second transistor is connected to the second initial signal line, and a second electrode of the second transistor is connected to the second node; and
a gate electrode of the third transistor is electrically connected to the third scan signal line, a first electrode of the third transistor is electrically connected to the third initial signal line, and a second electrode of the third transistor is electrically connected to the third node; or
wherein the compensation sub-circuit comprises a fourth transistor, and the write transistor comprises a fifth transistor;
a gate electrode of the fourth transistor is electrically connected to the first scan signal line, a first electrode of the fourth transistor is electrically connected to the fourth node, and a second electrode of the fourth transistor is electrically connected to the third node; and
a gate electrode of the fifth transistor is electrically connected to the fourth scan signal line, a first electrode of the fifth transistor is electrically connected to the data signal line, and a second electrode of the fifth transistor is electrically connected to the fourth node.

4. (canceled)

5. The pixel drive circuit according to claim 1, wherein the node control sub-circuit further comprises a first transistor to a fifth transistor, the drive sub-circuit comprises a sixth transistor, and the light emitting control sub-circuit comprises a seventh transistor;
a gate electrode of the first transistor is connected to the first scan signal line, a first electrode of the first transistor is connected to the first initial signal line, and a second electrode of the first transistor is connected to the first node;
a gate electrode of the second transistor is connected to the second scan signal line, a first electrode of the second transistor is connected to the second initial signal line, and a second electrode of the second transistor is connected to the second node;
a gate electrode of the third transistor is electrically connected to the third scan signal line, a first electrode of the third transistor is electrically connected to the third initial signal line, and a second electrode of the third transistor is electrically connected to the third node;
a gate electrode of the fourth transistor is electrically connected to the first scan signal line, a first electrode of the fourth transistor is electrically connected to the fourth node, and a second electrode of the fourth transistor is electrically connected to the third node;
a gate electrode of the fifth transistor is electrically connected to the fourth scan signal line, a first electrode of the fifth transistor is electrically connected to the data signal line, and a second electrode of the fifth transistor is electrically connected to the fourth node;
a gate electrode of the sixth transistor is electrically connected to the first node, a first electrode of the sixth transistor is electrically connected to the third node, and a second electrode of the sixth transistor is electrically connected to the second node; and
a gate electrode of the seventh transistor is electrically connected to the light emitting signal line, a first electrode of the seventh transistor is electrically connected to the first power supply line, and a second electrode of the seventh transistor is electrically connected to the third node.

6. The pixel drive circuit according to claim 5, wherein the first transistor, the fourth transistor, and the fifth transistor are oxide transistors and are N-type transistors, and the second transistor, the third transistor, the sixth transistor, and the seventh transistor are P-type transistors; and
a length of a channel region of an active layer of the sixth transistor is larger than a length of a channel region of an active layer of any one of the first transistor to the fifth transistor and the seventh transistor, a width of the channel region of the active layer of the sixth transistor is larger than a width of the channel region of the active layer of any one of the first transistor to the fifth transistor and the seventh transistor, and a width-length ratio of the channel region of the active layer of the sixth transistor is smaller than a width-length ratio of the channel region of the active layer of any one of the first transistor to the fifth transistor and the seventh transistor.

7. The pixel drive circuit according to claim 1, wherein the signal of the first scan signal line and the signal of the second scan signal line are mutually inverted signals;
when a signal of the third scan signal line is an active level signal, the signals of the first scan signal line and the second scan signal line are active level signals, and signals of the fourth scan signal line and the light emitting signal line are inactive level signals;
when the signal of the fourth scan signal line is an active level signal, the signals of the first scan signal line, the second scan signal line, the third scan signal line and the light emitting signal line are inactive level signals;
when the signal of the light emitting signal line is an active level signal, signals of the first scan signal line, the second scan signal line, the third scan signal line and the fourth scan signal line are inactive level signals; and
a duration for which a signal of any one of the first scan signal line and the second scan signal line is an active level signal is longer than a duration for which a signal of any one of the third scan signal line and the fourth scan signal line is an active level signal.

8. The pixel drive circuit according to claim 7, wherein a signal of the first initial signal line and a signal of the second initial signal line are a same signal, and a voltage value of the signal of the first initial signal line is smaller than a voltage value of the signal of the third initial signal line; and
the voltage value of the signal of the second initial signal line is greater than the voltage value of the signal of the second power supply line.

9. A display substrate comprising: a base substrate and a plurality of sub-pixels arranged on the base substrate, and at least one sub-pixel comprises the pixel drive circuit according to claim 1 and a light emitting device driven by the pixel drive circuit.

10. The display substrate according to claim 9, further comprising: a drive circuit layer and a light emitting structure layer which are sequentially stacked on the base substrate, wherein the drive circuit layer comprises a plurality of pixel drive circuits, a plurality of light emitting signal lines, a plurality of first initial signal lines, a plurality of second initial signal lines, a plurality of third initial signal lines, a plurality of first scan signal lines, a plurality of second scan signal lines, a plurality of third scan signal lines, a plurality of fourth scan signal lines, a plurality of first power supply lines and a plurality of data signal lines, and the light emitting structure layer comprises a light emitting device; and
any one of the light emitting signal lines, the first initial signal lines, the second initial signal lines, the third initial signal lines, the first scan signal lines, the second scan signal lines, the third scan signal lines and the fourth scan signal lines extends at least partially along a first direction, and any one of the first power supply lines and the data signal lines extends at least partially along a second direction, wherein the first direction intersects with the second direction.

11. The display substrate according to claim 10, wherein the drive circuit layer further comprises: a plurality of power supply connection lines extending at least partially along the first direction; and
at least one power supply connection line is connected to a pixel drive circuit and at least one first power supply line respectively;
wherein the pixel drive circuit further comprises a first connection electrode;
the first connection electrode is connected to the pixel drive circuit, a power supply connection line and a first power supply line respectively;
an orthographic projection of the first connection electrode on the base substrate is at least partially overlapped with orthographic projections of the power supply connection line and the first power supply line on the base substrate;
wherein a first initial signal line and a second initial signal line are a same signal line, and the drive circuit layer further comprises a plurality of initial connection lines extending at least partially along the second direction;
at least one initial connection line is connected to the pixel drive circuit and at least one first initial signal line respectively;
an orthographic projection of an initial connection line on the base substrate is located between orthographic projections of data signal lines connected by two adjacent columns of sub-pixels connected by the initial connection line on the base substrate;
wherein the first scan signal line comprises a first sub-signal line and a second sub-signal line electrically connected to each other, and the fourth scan signal line comprises a third sub-signal line and a fourth sub-signal line electrically connected to each other; and
an orthographic projection of the first sub-signal line on the base substrate is at least partially overlapped with an orthographic projection of the second sub-signal line on the base substrate, and an orthographic projection of the third sub-signal line on the base substrate is at least partially overlapped with an orthographic projection of the fourth sub-signal line on the base substrate.

12. (canceled)

13. (canceled)

14. (canceled)

15. The display substrate according to claim 11, wherein the pixel drive circuit comprises a first transistor to a seventh transistor and a first capacitor and a second capacitor; each of the first capacitor and the second capacitor comprises a first plate and a second plate respectively, and the drive circuit layer comprises a first semiconductor layer, a first conductive layer, a second conductive layer, a second semiconductor layer, a third conductive layer, a fourth conductive layer and a fifth conductive layer which are arranged sequentially on the base substrate;
the first semiconductor layer at least comprises an active layer of a second transistor, an active layer of a third transistor, an active layer of a sixth transistor and an active layer of a seventh transistor located in at least one pixel;
the first conductive layer at least comprises the light emitting signal lines, the second scan signal lines, the third scan signal lines, and a first plate of the first capacitor, a first plate of the second capacitor, a gate electrode of the second transistor, a gate electrode of the third transistor, a control electrode of the sixth transistor and a gate electrode of the seventh transistor located in at least one sub-pixel;
the second conductive layer at least comprises the first sub-signal line of the first scan signal line, the third sub-signal line of the fourth scan signal line, the second plate of the first capacitor and the second plate of the second capacitor located in at least one sub-pixel;
the second semiconductor layer at least comprises an active layer of the first transistor, an active layer of the fourth transistor and an active layer of the fifth transistor located in at least one sub-pixel;
the third conductive layer at least comprises the second sub-signal line of the first scan signal line, the fourth sub-signal line of the fourth scan signal line, the power supply connection line, the first initial signal line, the second initial signal line and the third initial signal line;
the fourth conductive layer at least comprises an initial connection line, and a first connection electrode and first electrodes and second electrodes of the first transistor to the seventh transistor located in at least one sub-pixel; and
the fifth conductive layer at least comprises the first power supply line and a data signal line.

16. The display substrate according to claim 15, wherein the drive circuit layer further comprises: a light shielding layer arranged between the base substrate and the first semiconductor layer;
the light shielding layer at least comprises a light shielding structure in at least one sub-pixel, and the light shielding structures of adjacent sub-pixels are connected to each other; and
an orthographic projection of the light shielding structure on the base substrate is at least partially overlapped with an orthographic projection of the gate electrode of the sixth transistor on the base substrate.

17. The display substrate according to claim 16, wherein the light shielding structure comprises a first light shielding portion, a second light shielding portion, a third light shielding portion, and a fourth light shielding portion; and
an orthographic projection of the first light shielding portion on the base substrate is at least partially overlapped with an orthographic projection of the active layer of the sixth transistor on the base substrate, an orthographic projection of the second light shielding portion on the base substrate is at least partially overlapped with an orthographic projection of the active layer of the seventh transistor on the base substrate, an orthographic projection of the third light shielding portion on the base substrate is at least partially overlapped with an orthographic projection of the active layer of the third transistor on the base substrate, and an orthographic projection of the fourth light shielding portion on the base substrate is at least partially overlapped with an orthographic projection of the active layer of the second transistor on the base substrate; or
wherein the light shielding structure comprises a light shielding portion, a first light shielding connection portion, a second light shielding connection portion, a third light shielding connection portion, and a fourth light shielding connection portion; and
an orthographic projection of the light shielding portion on the base substrate is at least partially overlapped with an orthographic projection of the active layer of the sixth transistor on the base substrate, and an orthographic projection of any one of the first light shielding connection portion, the second light shielding connection portion, the third light shielding connection portion and the fourth light shielding connection portion on the base substrate is not overlapped with an orthographic projection of any one of the active layer of the second transistor, the active layer of the third transistor and the active layer of the seventh transistor on the base substrate.

18. (canceled)

19. The display substrate according to claim 17, wherein a light emitting signal line connected to a sub-pixel is located on a side of a first plate of a second capacitor of the sub-pixel away from a first plate of a first capacitor of the sub-pixel, a second scan signal line connected to the sub-pixel is located on a side of the first plate of the first capacitor of the sub-pixel away from the first plate of the second capacitor of the sub-pixel, and a third scan signal line connected to the sub-pixel is located on a side of the second scan signal line connected to the sub-pixel away from the first plate of the first capacitor of the sub-pixel.

20. The display substrate according to claim 19, wherein a second plate of the first capacitor and a second plate of the second capacitor are connected to each other to form an integral structure, and are provided with a first via hole and a second via hole; the first via hole exposes the first plate of the first capacitor, and the second via hole exposes the second plate of the second capacitor;
the third sub-signal line of the fourth scan signal line is located on a side of the first sub-signal line of the first scan signal line away from the integral structure of the second plate of the first capacitor and the second plate of the second capacitor; and
an orthographic projection of the first sub-signal line of the first scan signal line connected to the sub-pixel on the base substrate is located between an orthographic projection of a light emitting signal line connected to the sub-pixel on the base substrate and an orthographic projection of the first plate of the second capacitor of the sub-pixel on the base substrate, and an orthographic projection of the third sub-signal line of the fourth scan signal line connected to the sub-pixel is located on a side of the orthographic projection of the light emitting signal line connected to the sub-pixel on the base substrate away from the orthographic projection of the first plate of the second capacitor of the sub-pixel on the base substrate.

21. The display substrate according to claim 20, wherein a second sub-signal line of a first scan signal line connected to the sub-pixel is located on a side of a fourth sub-signal line of a fourth scan signal line connected to the sub-pixel, a power supply connection line connected to the sub-pixel is located on a side of the second sub-signal line of the first scan signal line connected to the sub-pixel away from the fourth sub-signal line of the fourth scan signal line connected to the sub-pixel, a first initial signal line connected to the sub-pixel is located on a side of the power supply connection line connected to the sub-pixel away from the second sub-signal line of the first scan signal line connected to the sub-pixel, and a third initial signal line connected to the sub-pixel is located on a side of the first initial signal line connected to the sub-pixel away from the power supply connection line connected to the sub-pixel;
an orthographic projection of the fourth sub-signal line of the fourth scan signal line connected to the sub-pixel on the base substrate is located on a side of an orthographic projection of the light emitting signal line connected to the sub-pixel on the base substrate away from the orthographic projection of the first plate of the second capacitor of the sub-pixel on the base substrate;
an orthographic projection of the second sub-signal line of the first scan signal line connected to the sub-pixel on the base substrate is located between the orthographic projection of the light emitting signal line connected to the sub-pixel on the base substrate and the orthographic projection of the first plate of the second capacitor of the sub-pixel on the base substrate;
an orthographic projection of the power supply connection line connected to the sub-pixel on the base substrate is at least partially overlapped with an orthographic projection of the integral structure of the second plate of the first capacitor and the second plate of the second capacitor of the sub-pixel on the base substrate, and is located between the orthographic projection of the first sub-signal line of the first scan signal line on the base substrate and an orthographic projection of the second scan signal line on the base substrate;
an orthographic projection of the first initial signal line connected to the sub-pixel on the base substrate is at least partially overlapped with an orthographic projection of the second scan signal line connected to the sub-pixel on the base substrate, and is located between the orthographic projection of the first plate of the first capacitor of the sub-pixel on the base substrate and an orthographic projection of the third scan signal line connected to the sub-pixel on the base substrate; and
an orthographic projection of the third initial signal line connected to the sub-pixel on the base substrate is at least partially overlapped with the orthographic projection of the third scan signal line connected to the sub-pixel on the base substrate, and is located on a side of an orthographic projection of the second scan signal line connected to the sub-pixel on the base substrate away from an orthographic projection of the first plate of the first capacitor of the sub-pixel on the base substrate.

22. The display substrate according to claim 21, wherein the power supply connection line comprises a signal main body line, a first convex portion, a second convex portion and a third convex portion; the signal main body line extends along the first direction, the first convex portion is located on a side of the signal main body line close to the second sub-signal line of the first scan signal line, the second convex portion and the third convex portion are located on a side of the signal main body line away from the second sub-signal line of the first scan signal line, and the second convex portion and third convex portion are arranged along the first direction;
an orthographic projection of the second convex portion and an orthographic projection of the third convex portion on the base substrate are at least partially overlapped with an orthographic projection of the integral structure of the second plate of the first capacitor and the second plate of the second capacitor on the base substrate; and
an orthographic projection of the first via hole on the base substrate is located between the orthographic projection of the second convex portion on the base substrate and the orthographic projection of the third convex portion on the base substrate.

23. The display substrate according to claim 22, wherein an orthographic projection of the first connection electrode on the base substrate is at least partially overlapped with orthographic projections of the signal main body line, the second convex portion and the third convex portion of the power supply connection line on the base substrate, and is not overlapped with an orthographic projection of the first convex portion of the power supply connection line on the base substrate; or
wherein an orthographic projection of the first power supply line on the base substrate is at least partially overlapped with orthographic projections of the integral structure of the second electrode plate of the first capacitor and the second electrode plate of the second capacitor, the first connection electrode, the signal main body portion and the second convex portion of the power supply connection line on the base substrate; and
an orthographic projection of the first power supply line connected to a sub-pixel on the base substrate is located on a side of the data signal line connected to the sub-pixel away from the initial connection line connected to the sub-pixel.

24. (canceled)

25. A display apparatus, comprising: the display substrate according to claim 9.

26. A method for driving a pixel drive circuit, configured to drive the pixel drive circuit according to claim 1, the method comprising following steps:
the node control sub-circuit driving a signal of the first node, providing a signal of the second initial signal line to the second node, and providing a signal of the third initial signal line to the third node through signals of the first initial signal line, the data signal line and the first power supply line under control of signals of the first scan signal line, the second scan signal line, the third scan signal line and the fourth scan signal line; and
the light emitting control sub-circuit providing a signal of the first power supply line to the third node under control of a signal of the light emitting signal line, and the drive sub-circuit outputting a drive current to the second node under control of signals of the first node and the third node.
